(19) United States
(12) Patent Application Publication
(10) Pub. No.: US 2014/0151756 A1
(43) Pub. Date: Jun. 5, 2014

(54) FIN FIELD EFFECT TRANSISTORS INCLUDING COMPLIMENTARILY STRESSED CHANNELS

(71) Applicant: INTERNATIONAL BUSINESS MACHINES CORPORATION, Armonk, NY (US)

(72) Inventors: Josephine B. Chang, Mahopac, NY (US); Paul Chang, Mahopac, NY (US); Michael A. Guillorn, Yorktown Heights, NY (US); Amlan Majumdar, White Plains, NY (US)

(73) Assignee: International Business Machines Corporation, Armonk, NY (US)

(21) Appl. No.: 13/692,144

(22) Filed: Dec. 3, 2012

(51) Int. Cl. H01L 29/78; H01L 29/66

(52) U.S. Cl. CPC H01L 29/78; H01L 29/66477
USPC 257/288; 438/299

(57) ABSTRACT

A stressed single crystalline epitaxial semiconductor layer having a first type stress is formed on a single crystalline substrate layer. First and second semiconductor fins are formed by patterning the stressed single crystalline epitaxial semiconductor layer. A center portion of each first semiconductor fin is undercut to form a recessed region, while the bottom surface of each second semiconductor fin maintains epitaxial registry with the single crystalline substrate layer. The center portion of each first semiconductor fin is under a second type of stress, which is the opposite of the first type of stress. A first field effect transistor formed on the first semiconductor fins can include first channels under the second type of stress along direction of current flow, and a second field effect transistor formed on the second semiconductor fins can include second channels under the first type of stress along the direction of current flow.

### BACKGROUND

The present disclosure relates to a semiconductor structure, and particularly to fin field effect transistors including complimentarily stressed channels and a method of manufacturing the same.

In many semiconductor materials, complimentary stress is desirable in order to enhance the mobility of p-type field effect transistors and n-type field effect transistors. For example, a compressive stress along the direction of a silicon channel of a p-type field effect transistor increases the mobility of minority charge carriers (i.e., holes), while a tensile stress along the direction of a silicon channel of an n-type field effect transistor increase the mobility of minority charge carriers (i.e., electrons). Thus, complimentarily stressed semiconductor nanowires are desirable in order to provide a combination of high performance p-type fin field effect transistors and high performance n-type field effect transistors.

### BRIEF SUMMARY

A stressed single crystalline epitaxial semiconductor layer having a first type stress is formed on a single crystalline substrate layer. First and second semiconductor fins are formed by patterning the stressed single crystalline epitaxial semiconductor layer. A center portion of each first semiconductor fin is undercut to form a recessed region within the single crystalline substrate layer, while the bottom surface of each second semiconductor fin maintains epitaxial registry with the single crystalline substrate layer. The center portion of each first semiconductor fin is under a second type of stress, which is the opposite of the first type of stress, along the lengthwise direction of the first semiconductor fin. A first field effect transistor can be formed on the first semiconductor fins, and can include first channels under the second type of stress along direction of current flow, and a second field effect transistor can be formed on the second semiconductor fins, and can include second channels under the first type of stress along the direction of current flow.

According to an aspect of the present disclosure, a method of forming a semiconductor structure is provided. At least one semiconductor fin is formed on a single crystalline substrate layer. The at least one semiconductor fin includes a single crystalline semiconductor material epitaxially aligned to, and lattice-mismatched from, the single crystalline substrate layer and extends along a lengthwise direction. A recessed region is formed in the single crystalline substrate layer. A first end portion and a second end portion of each of the at least one semiconductor fin remains in contact with a top surface of the single crystalline substrate layer, and a center portion of each of the at least one semiconductor fin overlies the recessed region.

According to another aspect of the present disclosure, a semiconductor structure includes a single crystalline substrate layer including a recessed region that is recessed relative to a top surface of the single crystalline substrate layer. The semiconductor structure further includes a semiconductor fin including a single crystalline semiconductor material including first and second end portions that are in contact with the top surface of the single crystalline substrate layer and epitaxially aligned to the single crystalline substrate layer and including a center portion that overlies the recessed region. The single crystalline semiconductor material is lattice-mismatched with respect to the single crystalline substrate layer.

### BRIEF DESCRIPTION OF SEVERAL VIEWS OF THE DRAWINGS

FIG. 1A is a top-down view of a first exemplary semiconductor structure after formation of an optional dielectric cap layer and a plurality of fin-defining mask structures in each of a first device region and a second device region according to an embodiment of the present disclosure.

FIG. 1B is a vertical cross-sectional view of the first exemplary semiconductor structure along the vertical plane B-B′ of FIG. 1A.

FIG. 2A is a top-down view of a region selected from the first and second device regions of the first exemplary semiconductor structure according to an embodiment of the present disclosure.

FIG. 2B is a vertical cross-sectional view of the first exemplary semiconductor structure along the vertical plane B-B′ of FIG. 2A.

FIG. 2C is a vertical cross-sectional view of the first exemplary semiconductor structure along the vertical plane C-C′ of FIG. 2A.

FIG. 2D is a vertical cross-sectional view of the first exemplary semiconductor structure along the vertical plane D-D′ of FIG. 2A.

FIG. 3A is a top-down view of the selected region of the first exemplary semiconductor structure after patterning of an epitaxial semiconductor layer to form a plurality of semiconductor fins according to an embodiment of the present disclosure.

FIG. 3B is a vertical cross-sectional view of the selected region of the first exemplary semiconductor structure along the vertical plane B-B′ of FIG. 3A.

FIG. 3C is a vertical cross-sectional view of the selected region of the first exemplary semiconductor structure along the vertical plane C-C′ of FIG. 3A.

FIG. 3D is a vertical cross-sectional view of the selected region of the first exemplary semiconductor structure along the vertical plane D-D′ of FIG. 3A.

FIG. 4A is a top-down view of the first device region of the first exemplary semiconductor structure after formation of a patterned photoresist layer according to an embodiment of the present disclosure.

FIG. 4B is a vertical cross-sectional view of the first device region of the first exemplary semiconductor structure along the vertical plane B-B′ of FIG. 4A.

FIG. 4C is a vertical cross-sectional view of the first device region of the first exemplary semiconductor structure along the vertical plane C-C′ of FIG. 4A.

FIG. 4D is a vertical cross-sectional view of the first device region of the first exemplary semiconductor structure along the vertical plane D-D′ of FIG. 4A.

FIG. 4E is a top-down view of the second device region of the first exemplary semiconductor structure after formation of the patterned photoresist layer according to an embodiment of the present disclosure.

FIG. 4F is a vertical cross-sectional view of the second device region of the first exemplary semiconductor structure along the vertical plane F-F′ of FIG. 4E.

FIG. 4G is a vertical cross-sectional view of the second device region of the first exemplary semiconductor structure along the vertical plane G-G′ of FIG. 4F.

FIG. 4H is a vertical cross-sectional view of the second device region of the first exemplary semiconductor structure along the vertical plane H-H′ of FIG. 4G.

FIG. 5A is a top-down view of the first device region of the first exemplary semiconductor structure after formation of a recessed region in a single crystalline substrate layer according to an embodiment of the present disclosure.

FIG. 5B is a vertical cross-sectional view of the first device region of the first exemplary semiconductor structure along the vertical plane B-B′ of FIG. 5A.

FIG. 5C is a vertical cross-sectional view of the first device region of the first exemplary semiconductor structure along the vertical plane C-C′ of FIG. 5A.

FIG. 5D is a vertical cross-sectional view of the first device region of the first exemplary semiconductor structure along the vertical plane D-D′ of FIG. 5A.

FIG. 5E is a top-down view of the second device region of the first exemplary semiconductor structure after formation of a recessed region in a single crystalline substrate layer in the first device region according to an embodiment of the present disclosure.

FIG. 5F is a vertical cross-sectional view of the second device region of the first exemplary semiconductor structure along the vertical plane F-F′ of FIG. 5E.

FIG. 5G is a vertical cross-sectional view of the second device region of the first exemplary semiconductor structure along the vertical plane G-G′ of FIG. 5F.

FIG. 5H is a vertical cross-sectional view of the second device region of the first exemplary semiconductor structure along the vertical plane H-H′ of FIG. 5G.

FIG. 6A is a top-down view of the first device region of the first exemplary semiconductor structure after removal of the patterned photoresist layer according to an embodiment of the present disclosure.

FIG. 6B is a vertical cross-sectional view of the first device region of the first exemplary semiconductor structure along the vertical plane B-B′ of FIG. 6A.

FIG. 6C is a vertical cross-sectional view of the first device region of the first exemplary semiconductor structure along the vertical plane C-C′ of FIG. 6A.

FIG. 6D is a vertical cross-sectional view of the first device region of the first exemplary semiconductor structure along the vertical plane D-D′ of FIG. 6A.

FIG. 7A is a top-down view of the first device region of the first exemplary semiconductor structure after formation of a gate dielectric and a gate electrode according to an embodiment of the present disclosure.

FIG. 7B is a vertical cross-sectional view of the first device region of the first exemplary semiconductor structure along the vertical plane B-B′ of FIG. 7A.

FIG. 7C is a vertical cross-sectional view of the first device region of the first exemplary semiconductor structure along the vertical plane C-C′ of FIG. 7A.

FIG. 7D is a vertical cross-sectional view of the first device region of the first exemplary semiconductor structure along the vertical plane D-D′ of FIG. 7A.

FIG. 8A is a top-down view of the first device region of the first exemplary semiconductor structure after formation of a gate spacer and raised source/drain regions according to an embodiment of the present disclosure.

FIG. 8B is a vertical cross-sectional view of the first device region of the first exemplary semiconductor structure along the vertical plane B-B′ of FIG. 8A.

FIG. 8C is a vertical cross-sectional view of the first device region of the first exemplary semiconductor structure along the vertical plane C-C′ of FIG. 8A.

FIG. 8D is a vertical cross-sectional view of the first device region of the first exemplary semiconductor structure along the vertical plane D-D′ of FIG. 8A.

FIG. 8E is a top-down view of the second device region of the first exemplary semiconductor structure after formation of a gate spacer and raised source/drain regions according to an embodiment of the present disclosure.

FIG. 8F is a vertical cross-sectional view of the second device region of the first exemplary semiconductor structure along the vertical plane F-F′ of FIG. 8E.

FIG. 8G is a vertical cross-sectional view of the second device region of the first exemplary semiconductor structure along the vertical plane G-G′ of FIG. 8F.

FIG. 8H is a vertical cross-sectional view of the second device region of the first exemplary semiconductor structure along the vertical plane H-H′ of FIG. 8G.

FIG. 9A is a top-down view of the first device region of the first exemplary semiconductor structure after formation of a contact level dielectric layer and contact via structures according to an embodiment of the present disclosure.

FIG. 9B is a vertical cross-sectional view of the first device region of the first exemplary semiconductor structure along the vertical plane B-B′ of FIG. 9A.

FIG. 9C is a vertical cross-sectional view of the first device region of the first exemplary semiconductor structure along the vertical plane C-C′ of FIG. 9A.

FIG. 9D is a vertical cross-sectional view of the first device region of the first exemplary semiconductor structure along the vertical plane D-D′ of FIG. 9A.

FIG. 10A is a top-down view of the first device region of a second exemplary semiconductor structure including disposable gate stacks after formation of a planarization dielectric layer according to an embodiment of the present disclosure.

FIG. 10B is a vertical cross-sectional view of the first device region of the second exemplary semiconductor structure along the vertical plane B-B′ of FIG. 10A.

FIG. 10C is a vertical cross-sectional view of the first device region of the second exemplary semiconductor structure along the vertical plane C-C′ of FIG. 10A.

FIG. 10D is a vertical cross-sectional view of the first device region of the second exemplary semiconductor structure along the vertical plane D-D′ of FIG. 10A.

FIG. 11A is a top-down view of the first device region of the second exemplary semiconductor structure after removal of the disposable gate stack according to an embodiment of the present disclosure.

FIG. 11B is a vertical cross-sectional view of the first device region of the second exemplary semiconductor structure along the vertical plane B-B′ of FIG. 11A.

FIG. 11C is a vertical cross-sectional view of the first device region of the second exemplary semiconductor structure along the vertical plane C-C′ of FIG. 11A.

FIG. 11D is a vertical cross-sectional view of the first device region of the second exemplary semiconductor structure along the vertical plane D-D′ of FIG. 11A.

FIG. 12A is a top-down view of the first device region of the second exemplary semiconductor structure after formation of a replacement gate structure according to an embodiment of the present disclosure.

FIG. 12B is a vertical cross-sectional view of the first device region of the second exemplary semiconductor structure along the vertical plane B-B′ of FIG. 12A.

FIG. 12C is a vertical cross-sectional view of the first device region of the second exemplary semiconductor structure along the vertical plane C-C′ of FIG. 12A.

FIG. 12D is a vertical cross-sectional view of the first device region of the second exemplary semiconductor structure along the vertical plane D-D′ of FIG. 12A.

FIG. 13A is a top-down view of the first device region of the second exemplary semiconductor structure after formation of a contact level dielectric layer and contact via structures according to an embodiment of the present disclosure.

FIG. 13B is a vertical cross-sectional view of the first device region of the second exemplary semiconductor structure along the vertical plane B-B′ of FIG. 13A.

FIG. 13C is a vertical cross-sectional view of the first device region of the second exemplary semiconductor structure along the vertical plane C-C′ of FIG. 13A.

FIG. 13D is a vertical cross-sectional view of the first device region of the second exemplary semiconductor structure along the vertical plane D-D′ of FIG. 13A.

FIG. 13E is a top-down view of the second device region of the second exemplary semiconductor structure after formation of the contact level dielectric layer and contact via structures according to an embodiment of the present disclosure.

FIG. 13F is a vertical cross-sectional view of the second device region of the second exemplary semiconductor structure along the vertical plane F-F′ of FIG. 13E.

FIG. 13G is a vertical cross-sectional view of the second device region of the second exemplary semiconductor structure along the vertical plane G-G′ of FIG. 13F.

FIG. 13H is a vertical cross-sectional view of the second device region of the second exemplary semiconductor structure along the vertical plane H-H′ of FIG. 13G.

FIG. 14A is a top-down view of a selected region of a third exemplary semiconductor structure after patterning of an epitaxial semiconductor layer to form an epitaxial semiconductor portion according to an embodiment of the present disclosure.

FIG. 14B is a vertical cross-sectional view of the selected region of the third exemplary semiconductor structure along the vertical plane B-B′ of FIG. 14A.

FIG. 14C is a vertical cross-sectional view of the selected region of the third exemplary semiconductor structure along the vertical plane C-C′ of FIG. 14A.

FIG. 14D is a vertical cross-sectional view of the selected region of the third exemplary semiconductor structure along the vertical plane D-D′ of FIG. 14A.

FIG. 15A is a top-down view of the selected region of the third exemplary semiconductor structure after formation of a disposable gate structure and a disposable gate cap according to an embodiment of the present disclosure.

FIG. 15B is a vertical cross-sectional view of the selected region of the third exemplary semiconductor structure along the vertical plane B-B′ of FIG. 15A.

FIG. 15C is a vertical cross-sectional view of the selected region of the third exemplary semiconductor structure along the vertical plane C-C′ of FIG. 15A.

FIG. 15D is a vertical cross-sectional view of the selected region of the third exemplary semiconductor structure along the vertical plane D-D′ of FIG. 15A.

FIG. 16A is a top-down view of the selected region of the third exemplary semiconductor structure after formation of a gate spacer and removal of portions of the plurality of fin-defining mask structures that are not covered by the disposable gate structure or by the gate spacer according to an embodiment of the present disclosure.

FIG. 16B is a vertical cross-sectional view of the selected region of the third exemplary semiconductor structure along the vertical plane B-B′ of FIG. 16A.

FIG. 16C is a vertical cross-sectional view of the selected region of the third exemplary semiconductor structure along the vertical plane C-C′ of FIG. 16A.

FIG. 16D is a vertical cross-sectional view of the selected region of the third exemplary semiconductor structure along the vertical plane D-D′ of FIG. 16A.

FIG. 17A is a top-down view of the selected region of the third exemplary semiconductor structure after recessing portions of the patterned epitaxial semiconductor layer that are not covered by the disposable gate structure or by the gate spacer according to an embodiment of the present disclosure.

FIG. 17B is a vertical cross-sectional view of the selected region of the third exemplary semiconductor structure along the vertical plane B-B′ of FIG. 17A.

FIG. 17C is a vertical cross-sectional view of the selected region of the third exemplary semiconductor structure along the vertical plane C-C′ of FIG. 17A.

FIG. 17D is a vertical cross-sectional view of the selected region of the third exemplary semiconductor structure along the vertical plane D-D′ of FIG. 17A.

FIG. 18A is a top-down view of the selected region of the third exemplary semiconductor structure after selective epitaxial growth of stress-generating semiconductor portions according to an embodiment of the present disclosure.

FIG. 18B is a vertical cross-sectional view of the selected region of the third exemplary semiconductor structure along the vertical plane B-B′ of FIG. 18A.

FIG. 18C is a vertical cross-sectional view of the selected region of the third exemplary semiconductor structure along the vertical plane C-C′ of FIG. 18A.

FIG. 18D is a vertical cross-sectional view of the selected region of the third exemplary semiconductor structure along the vertical plane D-D′ of FIG. 18A.

FIG. 19A is a top-down view of the selected region of the third exemplary semiconductor structure after formation of metal semiconductor alloy portions according to an embodiment of the present disclosure.

FIG. 19B is a vertical cross-sectional view of the selected region of the third exemplary semiconductor structure along the vertical plane B-B′ of FIG. 19A.

FIG. 19C is a vertical cross-sectional view of the selected region of the third exemplary semiconductor structure along the vertical plane C-C′ of FIG. 19A.

FIG. 19D is a vertical cross-sectional view of the selected region of the third exemplary semiconductor structure along the vertical plane D-D′ of FIG. 19A.

FIG. 20A is a top-down view of the selected region of the third exemplary semiconductor structure after formation and planarization of a planarization dielectric layer according to an embodiment of the present disclosure.

FIG. 20B is a vertical cross-sectional view of the selected region of the third exemplary semiconductor structure along the vertical plane B-B′ of FIG. 20A.

FIG. 20C is a vertical cross-sectional view of the selected region of the third exemplary semiconductor structure along the vertical plane C-C′ of FIG. 20A.

FIG. 20D is a vertical cross-sectional view of the selected region of the third exemplary semiconductor structure along the vertical plane D-D′ of FIG. 20A.

FIG. 21A is a top-down view of the selected region of the third exemplary semiconductor structure after further planarization of the planarization dielectric layer and the disposable gate cap according to an embodiment of the present disclosure.

FIG. 21B is a vertical cross-sectional view of the selected region of the third exemplary semiconductor structure along the vertical plane B-B′ of FIG. 21A.

FIG. 21C is a vertical cross-sectional view of the selected region of the third exemplary semiconductor structure along the vertical plane C-C′ of FIG. 21A.

FIG. 21D is a vertical cross-sectional view of the selected region of the third exemplary semiconductor structure along the vertical plane D-D′ of FIG. 21A.

FIG. 22A is a top-down view of the selected region of the third exemplary semiconductor structure after removal of the disposable gate structure according to an embodiment of the present disclosure.

FIG. 22B is a vertical cross-sectional view of the selected region of the third exemplary semiconductor structure along the vertical plane B-B′ of FIG. 22A.

FIG. 22C is a vertical cross-sectional view of the selected region of the third exemplary semiconductor structure along the vertical plane C-C′ of FIG. 22A.

FIG. 22D is a vertical cross-sectional view of the selected region of the third exemplary semiconductor structure along the vertical plane D-D′ of FIG. 22A.

FIG. 23A is a top-down view of the selected region of the third exemplary semiconductor structure after formation of a plurality of semiconductor fins by transfer of the pattern of the plurality of fin-defining mask structures into the patterned epitaxial semiconductor layer according to an embodiment of the present disclosure.

FIG. 23B is a vertical cross-sectional view of the selected region of the third exemplary semiconductor structure along the vertical plane B-B′ of FIG. 23A.

FIG. 23C is a vertical cross-sectional view of the selected region of the third exemplary semiconductor structure along the vertical plane C-C′ of FIG. 23A.

FIG. 23D is a vertical cross-sectional view of the selected region of the third exemplary semiconductor structure along the vertical plane D-D′ of FIG. 23A.

FIG. 24A is a top-down view of the first device region of the third exemplary semiconductor structure after formation of a recessed region in the single crystalline substrate layer according to an embodiment of the present disclosure.

FIG. 24B is a vertical cross-sectional view of the first device region of the third exemplary semiconductor structure along the vertical plane B-B′ of FIG. 24A.

FIG. 24C is a vertical cross-sectional view of the first device region of the third exemplary semiconductor structure along the vertical plane C-C′ of FIG. 24A.

FIG. 24D is a vertical cross-sectional view of the first device region of the third exemplary semiconductor structure along the vertical plane D-D′ of FIG. 24A.

FIG. 24E is a top-down view of the second device region of the third exemplary semiconductor structure after formation of the recessed region in the single crystalline substrate layer in the first device region according to an embodiment of the present disclosure.

FIG. 24F is a vertical cross-sectional view of the second device region of the third exemplary semiconductor structure along the vertical plane F-F′ of FIG. 24E.

FIG. 24G is a vertical cross-sectional view of the second device region of the third exemplary semiconductor structure along the vertical plane G-G′ of FIG. 24F.

FIG. 24H is a vertical cross-sectional view of the second device region of the third exemplary semiconductor structure along the vertical plane H-H′ of FIG. 24G.

FIG. 25A is a top-down view of the first device region of the third exemplary semiconductor structure after formation of a gate dielectric and a gate electrode according to an embodiment of the present disclosure.

FIG. 25B is a vertical cross-sectional view of the first device region of the third exemplary semiconductor structure along the vertical plane B-B′ of FIG. 25A.

FIG. 25C is a vertical cross-sectional view of the first device region of the third exemplary semiconductor structure along the vertical plane C-C′ of FIG. 25A.

FIG. 25D is a vertical cross-sectional view of the first device region of the third exemplary semiconductor structure along the vertical plane D-D′ of FIG. 25A.

FIG. 26A is a top-down view of the first device region of the third exemplary semiconductor structure after formation of a contact level dielectric layer and contact via structures according to an embodiment of the present disclosure.

FIG. 26B is a vertical cross-sectional view of the first device region of the third exemplary semiconductor structure along the vertical plane B-B′ of FIG. 26A.

FIG. 26C is a vertical cross-sectional view of the first device region of the third exemplary semiconductor structure along the vertical plane C-C′ of FIG. 26A.

FIG. 26D is a vertical cross-sectional view of the first device region of the third exemplary semiconductor structure along the vertical plane D-D′ of FIG. 26A.

FIG. 26E is a top-down view of the second device region of the third exemplary semiconductor structure after formation of the contact level dielectric layer and the contact via structures according to an embodiment of the present disclosure.

FIG. 26F is a vertical cross-sectional view of the second device region of the third exemplary semiconductor structure along the vertical plane F-F′ of FIG. 26E.

FIG. 26G is a vertical cross-sectional view of the second device region of the third exemplary semiconductor structure along the vertical plane G-G′ of FIG. 26F.

FIG. 26H is a vertical cross-sectional view of the second device region of the third exemplary semiconductor structure along the vertical plane H-H′ of FIG. 26G.

FIG. 27A is a top-down view of a region selected from first and second device regions of a fourth exemplary semiconductor structure after formation of a fin-containing semiconductor structure according to an embodiment of the present disclosure.

FIG. 27B is a vertical cross-sectional view of the region of the fourth exemplary semiconductor structure along the vertical plane B-B′ of FIG. 27A.

FIG. 27C is a vertical cross-sectional view of the region of the fourth exemplary semiconductor structure along the vertical plane C-C′ of FIG. 27A.

FIG. 27D is a vertical cross-sectional view of the region of the fourth exemplary semiconductor structure along the vertical plane D-D′ of FIG. 27A.

FIG. 28A is a top-down view of the first device region of the fourth exemplary semiconductor structure after formation of a recessed region in a single crystalline substrate layer according to an embodiment of the present disclosure.

FIG. 28B is a vertical cross-sectional view of the first device region of the fourth exemplary semiconductor structure along the vertical plane B-B′ of FIG. 29A.

FIG. 28C is a vertical cross-sectional view of the first device region of the fourth exemplary semiconductor structure along the vertical plane C-C′ of FIG. 29A.

FIG. 28D is a vertical cross-sectional view of the first device region of the fourth exemplary semiconductor structure along the vertical plane D-D′ of FIG. 29A.

FIG. 28E is a top-down view of the second device region of the fourth exemplary semiconductor structure after formation of a recessed region in a single crystalline substrate layer in the first device region according to an embodiment of the present disclosure.

FIG. 28F is a vertical cross-sectional view of the second device region of the fourth exemplary semiconductor structure along the vertical plane F-F′ of FIG. 29E.

FIG. 28G is a vertical cross-sectional view of the second device region of the fourth exemplary semiconductor structure along the vertical plane G-G′ of FIG. 29F.

FIG. 28H is a vertical cross-sectional view of the second device region of the fourth exemplary semiconductor structure along the vertical plane H-H′ of FIG. 29G.

FIG. 29A is a top-down view of the first device region of the fourth exemplary semiconductor structure after formation of a gate spacer and source/drain regions according to an embodiment of the present disclosure.

FIG. 29B is a vertical cross-sectional view of the first device region of the fourth exemplary semiconductor structure along the vertical plane B-B′ of FIG. 29A.

FIG. 29C is a vertical cross-sectional view of the first device region of the fourth exemplary semiconductor structure along the vertical plane C-C′ of FIG. 29A.

FIG. 29D is a vertical cross-sectional view of the first device region of the fourth exemplary semiconductor structure along the vertical plane D-D′ of FIG. 29A.

FIG. 29E is a top-down view of the second device region of the fourth exemplary semiconductor structure after formation of a gate spacer and source/drain regions according to an embodiment of the present disclosure.

FIG. 29F is a vertical cross-sectional view of the second device region of the fourth exemplary semiconductor structure along the vertical plane F-F′ of FIG. 29E.

FIG. 29G is a vertical cross-sectional view of the second device region of the fourth exemplary semiconductor structure along the vertical plane G-G′ of FIG. 29F.

FIG. 29H is a vertical cross-sectional view of the second device region of the fourth exemplary semiconductor structure along the vertical plane H-H′ of FIG. 29G.

### DETAILED DESCRIPTION

As stated above, the present disclosure relates to fin field effect transistors including complimentarily stressed channels and a method of manufacturing the same. Aspects of the present disclosure are now described in detail with accompanying figures. It is noted that like reference numerals refer to like elements across different embodiments. The drawings are not necessarily drawn to scale.

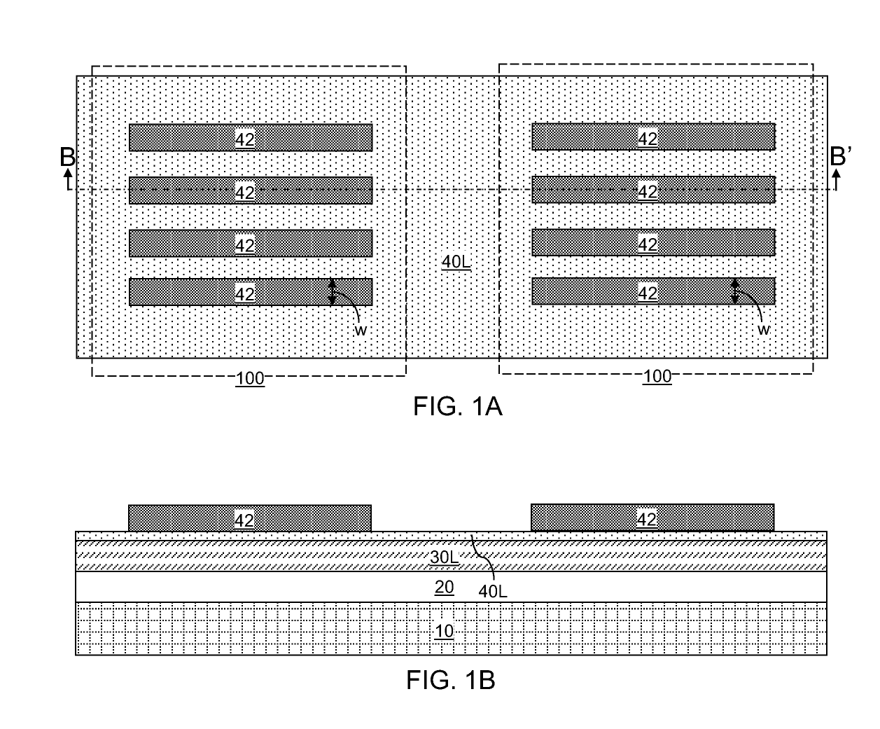

Referring to FIGS. 1A and 1B, a first exemplary semiconductor structure according to an embodiment of the present disclosure includes a vertical stack of a substrate 10, and a single crystalline substrate layer 20, and a epitaxial semiconductor layer 30L.

The substrate 10 can include a single crystalline semiconductor material, which can be a single crystalline compound semiconductor material or a single crystalline elemental semiconductor material or a single crystalline alloy of at least two elemental semiconductor materials. In one embodiment, the single crystalline semiconductor material of the substrate 10 can be a single crystalline III-V compound semiconductor material such as InSb, InP, InN, InGaSb, InGaP, InGaN, InGaAsSb, InGaAsP, InGaAsN, InGaAs, InAsSbP, InAsSb, InAs, InAlAsN, GaSb, GaP, GaN, GaInNAsSb, GaInAsSbP, GaAsSbN, GaAsSb, GaAsP, GaAsN, GaAs, BP, BN, BN, BAs, AlSb, AlP, AN, AlInSb, AlInAsP, AlInAs, AlGaP, AlGaN, AlGaInP, AlGaAsP, AlGaAsN, AlGaAs, and AlAs. In an illustrative example, the substrate 10 can include a single crystalline InP substrate.

In one embodiment, the substrate 10 can include a vertical stack of at least two different semiconductor materials having different compositions. The vertical stack can be formed, for example, by performing heteroepitaxy of at least one single crystalline semiconductor material on an underlying single crystalline semiconductor material layer. The at least one single crystalline semiconductor material deposited by heteroepitaxy can have a thickness greater than the relaxation thickness, and thus, provide a substantially strain-free top portion. The substantially strain-free top portion of the epitaxially deposited at least one single crystalline semiconductor material functions as a substrate having a different lattice constant than the lattice constant of the underlying single crystalline semiconductor material layer, and is referred to as a “virtual substrate,” i.e., a structure that simulates a substrate of the epitaxially deposited at least one single crystalline semiconductor material. In an illustrative example, the substrate 10 can include an underlying single crystalline semiconductor material layer that includes InP and an epitaxially deposited single crystalline semiconductor material of InAs.

The substrate 10 provides mechanical support to the single crystalline substrate layer 20 and the epitaxial semiconductor layer 30L. The thickness of the substrate 10 can be from 30 microns to 2 mm, although lesser and greater thicknesses can also be employed.

The single crystalline substrate layer 20 includes a single crystalline, electrically isolating material, which is herein referred to as a virtual substrate material. The virtual substrate material can be an insulator or a large-band-gap, intrinsic semiconductor. As used herein, an insulator refers to a material having a resistivity than 1.0×10⁵ Ohm-cm, a semiconductor refers to a material having a resistivity from 1.0×10⁻⁵ Ohm-cm to 1.0×10⁵ Ohm-cm, and a conductor refers to a material having a less than 1.0×10⁻⁵ Ohm-cm. An intrinsic semiconductor refers to a material that is a semiconductor in the absence of any electrical dopant (a p-type dopant or an n-type dopant). The virtual substrate material may be a single crystalline compound, a single crystalline elemental material, or a single crystalline alloy of at least two elemental materials. The single crystalline substrate layer 20 is epitaxially aligned to the single crystalline semiconductor material of the substrate 10. The thickness of the single crystalline substrate layer 20 can be from 50 nm to 5 microns, although lesser and greater thicknesses can also be employed.

The epitaxial semiconductor layer 30L includes another single crystalline semiconductor material that is different from the virtual substrate material. The semiconductor material of the epitaxial semiconductor layer 30L is herein referred to as an active material. The active material can be a single crystalline compound semiconductor material or a single crystalline elemental semiconductor material or a single crystalline alloy of at least two elemental semiconductor materials. The epitaxial semiconductor layer 30L is epitaxially aligned to the single crystalline substrate layer 20. The thickness of the epitaxial semiconductor layer 30L can be from 5 nm to 1,000 nm, although lesser and greater thicknesses can also be employed.

The virtual substrate material and the active material are selected such that a finite lattice mismatch exists between the two semiconductor materials. The magnitude of the lattice mismatch and the crystalline structures of the virtual substrate material and active materials are such that epitaxy of the active material upon the virtual substrate material is possible. Thus, the epitaxial semiconductor layer 30L is epitaxially aligned to, and is lattice-mismatched to, the single crystalline virtual substrate layer 20.

The lattice mismatch causes the active material in the epitaxial semiconductor layer 30L to be under a biaxial stress, which can be a compressive stress or a tensile stress. The type of stress in the epitaxial semiconductor layer 30L is herein referred to as a first type of stress, which is either compressive or tensile. In one embodiment, the virtual substrate material 20 can be InₓAl₍₁₋ₓ₎As, where x is chosen to be 0.52, for example, so as to be lattice-matched to an InP substrate 10, and the active material 30L can be In_{y}Ga_{(1-y)}As. For y>0.53, the biaxial strain in the epitaxial semiconductor layer 30L can be compressive, and for y<0.53, the biaxial strain in the epitaxial semiconductor layer 30L can be tensile. In another embodiment, the virtual substrate material 20 can be InₓAl₍ᵢ₋ₓ₎Sb, where x is chosen to be 0.2, for example, so as to be lattice-matched to an AlSb virtual substrate, and the active material 30L can be In_{y}As_{(1-y)}Sb. For y>0.2, the biaxial strain in the epitaxial semiconductor layer 30L is compressive, and for y<0.2, the biaxial strain in the epitaxial layer is tensile.

The greater the magnitude of the biaxial strain is in the epitaxial semiconductor layer 30, the lesser the critical thickness is, above which the epitaxially aligned active material becomes relaxed. The magnitude of the tensile strain or the magnitude of the compressive strain can be optimized in order to enhance the mobility of charge carriers in the epitaxial semiconductor layer 30L, while maintaining the epitaxial alignment of the active material to the virtual substrate material. In one embodiment, the magnitude of the biaxial strain can be in a range from 0 to 0.03, and the critical thickness can be in a range from 5 nm to 1,000 nm.

An optional dielectric liner layer 40L can be formed on the top surface of the epitaxial semiconductor layer 30L. The optional dielectric liner layer 40L includes a dielectric material, which can be, for example, silicon oxide, silicon oxynitride, a dielectric metal oxide, or a combination thereof. The optional dielectric liner layer 40L can be formed, for example, by chemical vapor deposition (CVD) or conversion of a topmost portion of the epitaxial semiconductor layer 30L by thermal oxidation, thermal nitridation, plasma oxidation, plasma nitridation, or a combination thereof. The thickness of the optional dielectric liner layer 40L can be from 1 nm to 20 nm, although lesser and greater thicknesses can also be employed.

A first plurality of fin-defining mask structures 42 is formed in a first device region 100, and a second plurality of fin-defining mask structures 42 is formed in a second device region 200. The first plurality of fin-defining mask structures 42 and the second plurality of fin-defining structures 42 can be formed over the epitaxial semiconductor layer 30L. Each plurality of fin-defining mask structures 42 can be formed directly on the optional dielectric liner layer 40L, if present. The first plurality of fin-defining mask structures 42 and the second plurality of fin-defining structures 42 are mask structures that cover the regions of the epitaxial semiconductor layer 30L that are subsequently converted into semiconductor fins. Thus, the first plurality of fin-defining mask structures 42 and the second plurality of fin-defining structures 42 are subsequently employed to define the area of the semiconductor fins. The first plurality of fin-defining mask structures 42 and the second plurality of fin-defining structures 42 can include a dielectric material such as silicon nitride, silicon oxide, and silicon oxynitride.

The first plurality of fin-defining mask structures 42 and the second plurality of fin-defining structures 42 can be formed, for example, by depositing a planar dielectric material layer and lithographically patterning the dielectric material layer. The planar dielectric material layer can be deposited, for example, by chemical vapor deposition (CVD). The thickness of the planar dielectric material layer can be from 5 nm to 100 nm, although lesser and greater thicknesses can also be employed.

The planar dielectric material layer can be subsequently patterned to form the first plurality of fin-defining mask structures 42 and the second plurality of fin-defining structures 42. In one embodiment, each fin-defining mask structure 42 can laterally extend along a lengthwise direction. Further, each fin-defining mask structure 42 can have a pair of sidewalls that are separated along a widthwise direction, which is perpendicular to the lengthwise direction. In one embodiment, each fin-defining mask structure 42 can have a rectangular horizontal cross-sectional area. In one embodiment, each fin-defining mask structures 42 can have the same width w.

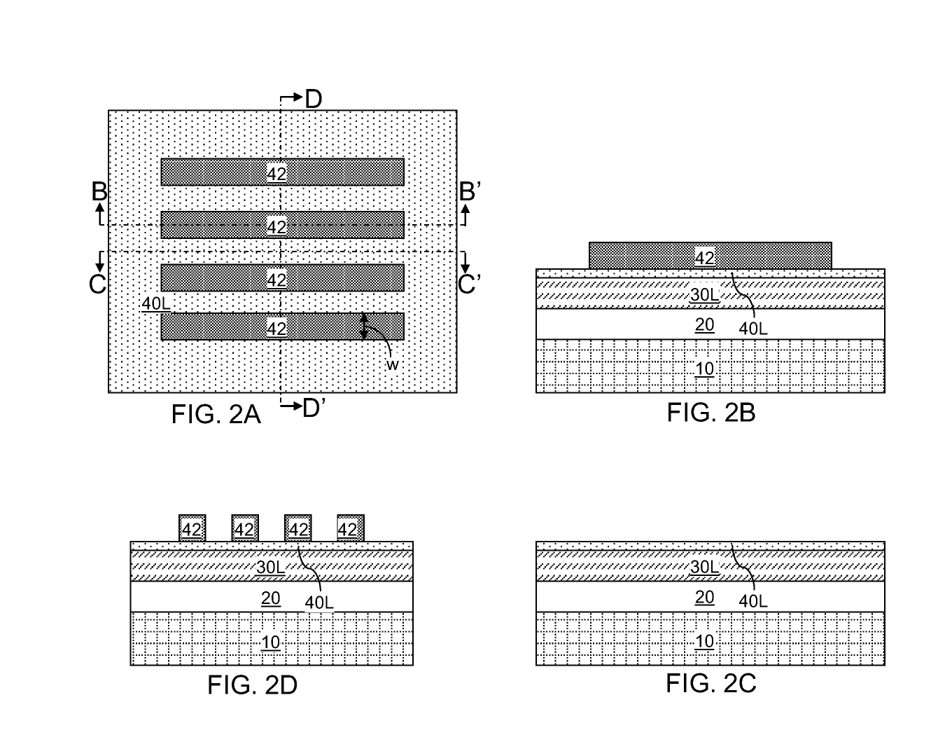

Referring to FIGS. 2A-2D, a selected region is shown in various views, which can be the first device regions 100 or the second device region 200 of the first exemplary semiconductor structure illustrated in FIGS. 1A and 1B. Because the structures of the first device region 100 and the second device region 200 are identical at this processing step, the selected region in the exemplary structure illustrated in FIGS. 2A-2D represents the structures of the first and second device regions (100, 200).

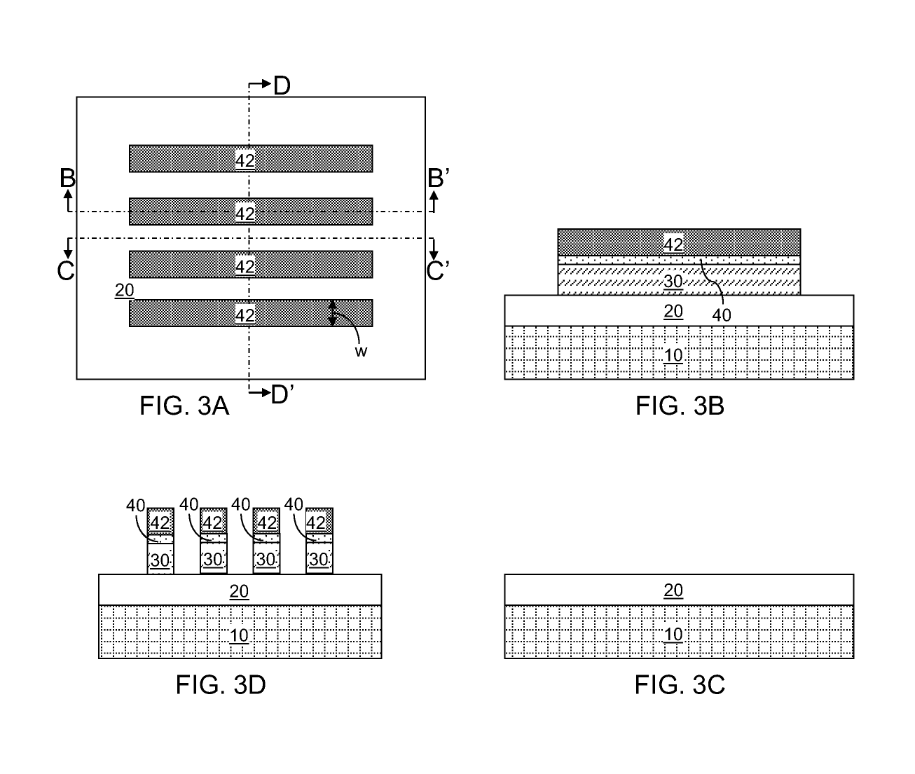

Referring to FIGS. 3A-3D, the same processing steps are subsequently performed to the first region 100 and the second region 200 shown in FIGS. 1A and 1B. The resulting semiconductor structure is illustrated with views of the selected region, which can be the first device regions 100 or the second device region 200.

The epitaxial semiconductor layer 30L is patterned to form at least one semiconductor fin 30 in each of the first and second regions (100, 200). The at least one semiconductor fin 30 can be a plurality of semiconductor fins 30. The at least one semiconductor fin 30 is formed on the single crystalline substrate layer 20. The at least one semiconductor fin 30 includes a single crystalline semiconductor material, i.e., the virtual substrate material, that is epitaxially aligned to, and lattice-mismatched from, the single crystalline substrate layer 20 and extends along a lengthwise direction.

The optional dielectric liner layer 40L, if present, is patterned into at least one optional dielectric liner portions 40. The sidewalls of each optional dielectric liner portion 40 can be vertically coincident with sidewalls of an overlying fin-defining mask structure 42 and with sidewalls of an underlying semiconductor fin 30. As used herein, a first surface and a second surface are vertically coincident if the first surface and the second surface are within a same curved or planar vertical plane.

The optional dielectric liner portions 40 and the fin-defining mask structures 42 are removed selective to the plurality of semiconductor fins 30. The removal of the optional dielectric liner portions 40 and the fin-defining mask structures 42 can be effected by an etch, which can be a wet etch or a dry etch. The optional dielectric liner portions 40 and the fin-defining mask structures 42 can be removed by a wet etch that removes dielectric materials selective to semiconductor materials. For example, a wet etch employing hot phosphoric acid can be employed to remove silicon nitride and/or a wet etch employing hydrofluoric acid can be employed to remove silicon oxide.

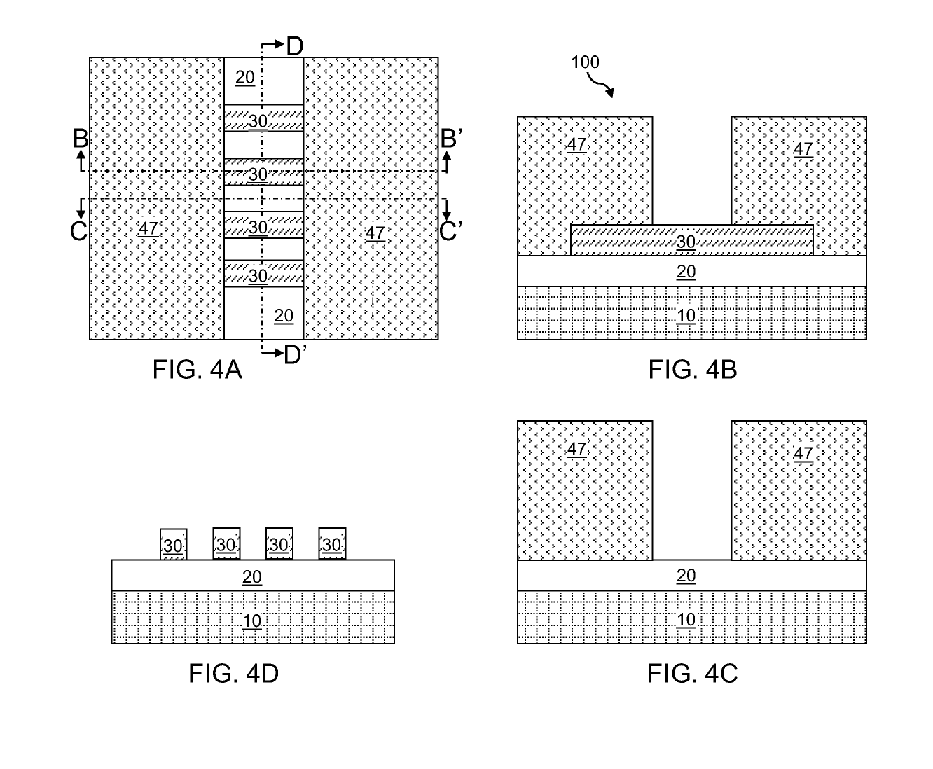

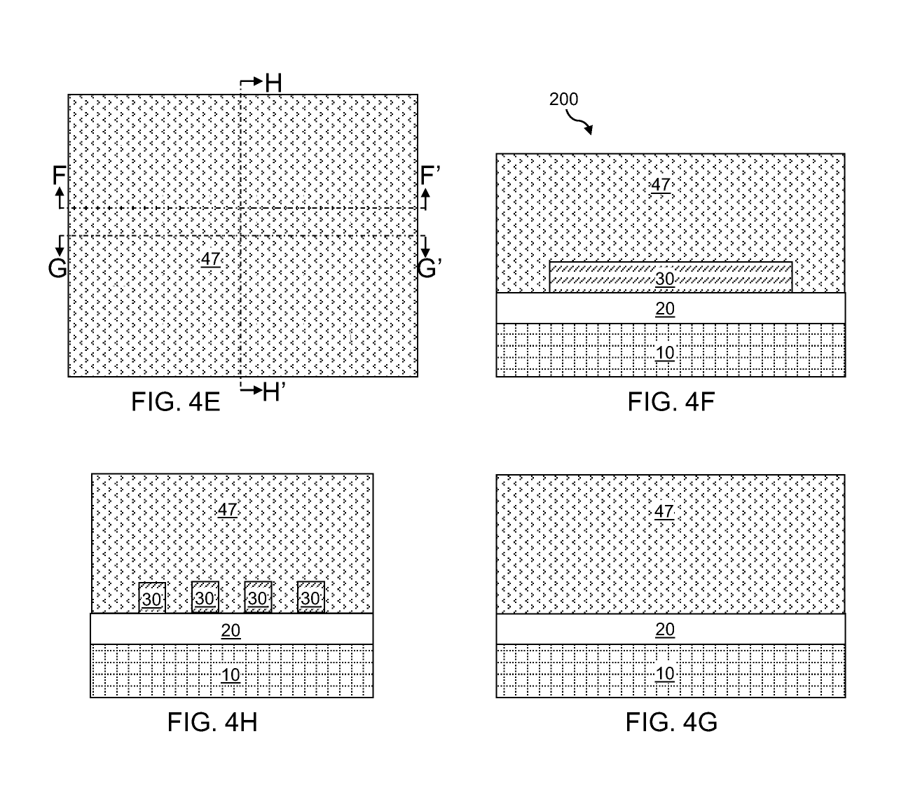

Referring to FIGS. 4A-4H, a patterned photoresist layer 47 is formed over the semiconductor fins and the single crystalline substrate layer 20. FIGS. 4A-4D show various views of the first device region 100, and FIGS. 4E-4H show various views of the second device region 200. The patterned photoresist layer 47 is formed by applying a blanket photoresist layer over the entirety of the single crystalline substrate layer 20, and subsequently patterning the blanket photoresist layer by lithographic means, i.e., by lithographic exposure and development.

The patterned photoresist layer 47 covers the entirety of the second device region 200, while a cavity straddling center portions of the semiconductor fins 30 is present within the patterned photoresist layer 47 in the first device region. The area of the cavity in the patterned photoresist layer 47 corresponds to an area in which a gate electrode is to be subsequently formed. Surfaces of the single crystalline substrate layer 20 are physically exposed at the bottom of the trench in the patterned photoresist layer 47.

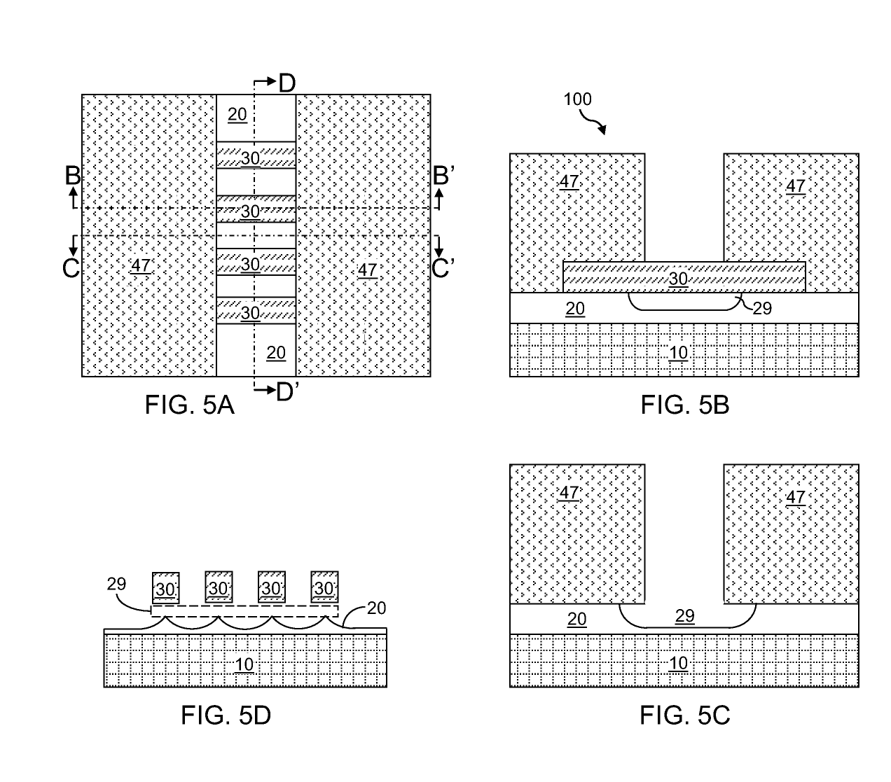

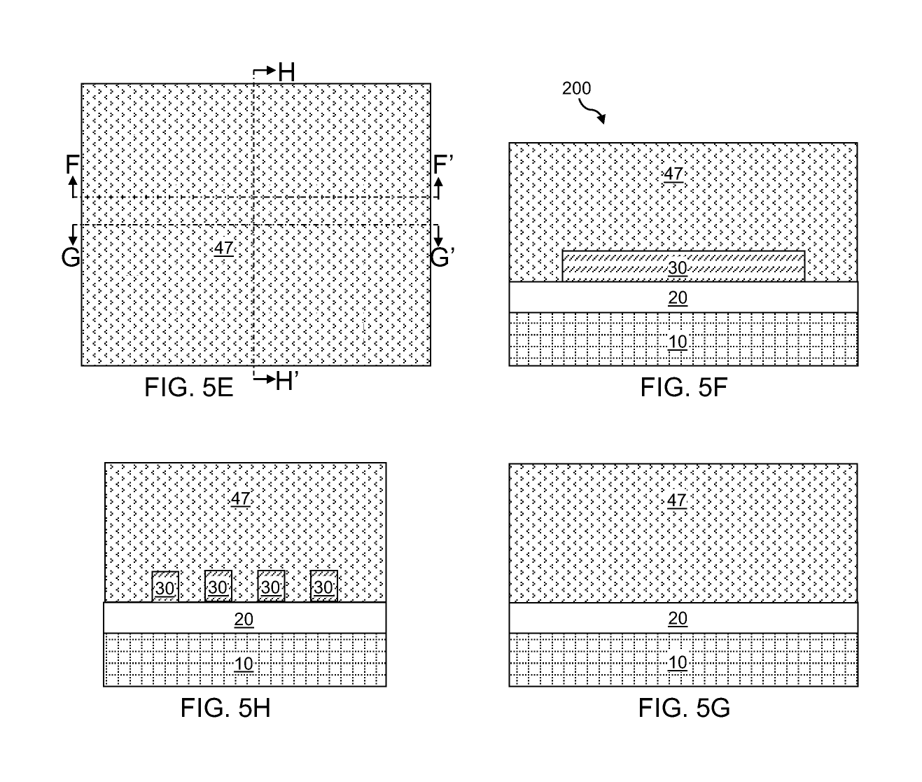

Referring to FIGS. 5A-5H, the virtual substrate material in physically exposed portions of the single crystalline substrate layer 20 are removed by an isotropic etch selective to the active material. The isotropic etch can be a wet etch or a dry etch. The chemistry of the isotropic etch is selected such that the virtual substrate material is etched selective to the active material, i.e., without significantly etching the active material.

In an illustrative embodiment, the virtual substrate material can be InAlAs, and the active material can be InGaAs. In this case, the isotropic etch can be a wet etch such as H₃PO₄:H₂O₂:H₂O solutions in the ratio ranging from 1:1:10 to 1:1:38. In another illustrative embodiment, the virtual substrate material can be InAlSb, and the active material can be InAsSb. In this case, the isotropic etch can be a dry etch employing CH₄/H₂/N₂/SiCl₄.

A recessed region 29 is formed in the single crystalline substrate layer 20 underneath center portions of the at least one semiconductor fin 30 in the first device region 100. As used herein, a “center portion” can be any portion that does not include an end portion. A first end portion and a second end portion of each of the at least one semiconductor fin 30 remains in contact with the top surface of the single crystalline substrate layer 20, and a center portion of each of the at least one semiconductor fin 30 within the first device region 100 overlies the recessed region 29.

The first and second end portions of each of the at least one semiconductor fin 30 are under the first type of stress due to epitaxial registry of the active material to the virtual substrate material in the single crystalline substrate layer 20 and due to the lattice mismatch between the active material and the virtual substrate material. Because the center portion of each semiconductor fin 30 within the first device region 100 is not epitaxially aligned to the single crystalline substrate layer 20, the center portion of each semiconductor fin 30 in the first device region can be under a second type of stress that is the opposite of the first type of stress along the lengthwise direction of the semiconductor fin 30. In one embodiment, the first type of stress can be compressive stress and the second type of stress can be tensile stress. In another embodiment, the first type of stress can be tensile stress and the second type of stress can be compressive stress.

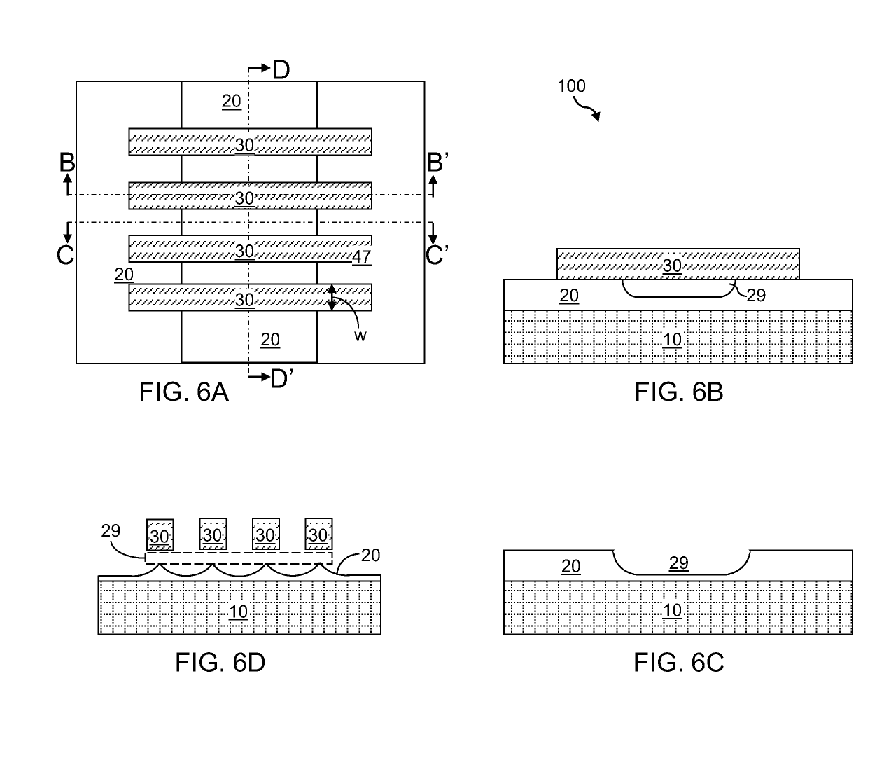

Referring to FIGS. 6A-6D, various views of the first device region 100 are shown after removal of the patterned photoresist layer 47 from above the single crystalline substrate layer 20 and the semiconductor fins 30.

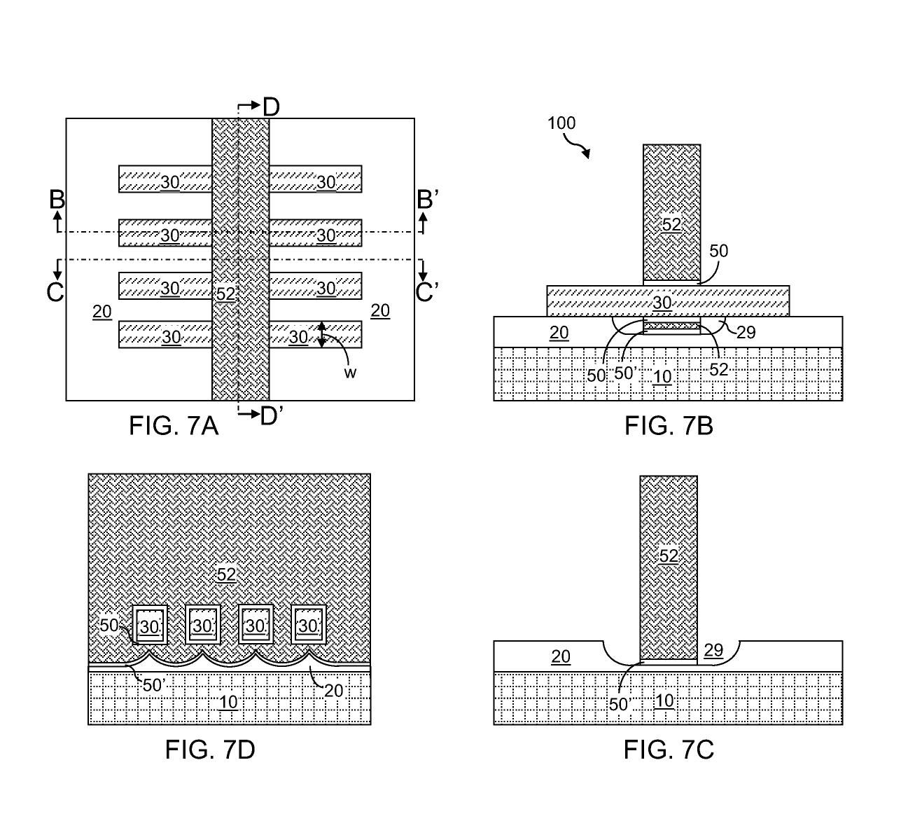

Referring to FIGS. 7A-7D, various view of the first device region 100 are shown after formation of a gate electrode 50 and a gate dielectric 52 in the first device region 100. While a single gate stack straddling the plurality of semiconductor fins 30 is illustrated in FIGS. 7A-7D, over the recessed portion of the single crystalline substrate layer 20, embodiments are expressly contemplated herein in which a plurality of gate stacks are formed to straddle the plurality of semiconductor fins 30 over the recessed portion of the single crystalline substrate layer 20. Another gate electrode (not shown) and another gate dielectric (not shown) can be formed in the second device region 200. The formation of the gate dielectric 50 and the gate electrode 52 can be effected, for example, by deposition of a gate dielectric layer and a gate electrode layer, and by subsequent patterning of the gate dielectric layer and the gate electrode layer by a combination of lithographic methods and at least one anisotropic etch. The gate dielectric 50 in the first device region 100 and the other gate dielectric (not shown) in the second device region 200 can include the same dielectric material or can include different dielectric materials. The gate electrode in the first device region 100 and the other gate electrode (not shown) in the second device region 200 can include the same conductive material(s) or can include different conductive materials.

The single crystalline substrate layer 20 includes the recessed region that is recessed relative to the top surface of the single crystalline substrate layer 20 within the first device region. Each semiconductor fin 30 in the first device region 100 includes a single crystalline semiconductor material (which is the active material) and includes first and second end portions, which are in contact with the top surface of the single crystalline substrate layer 10 and are epitaxially aligned to the single crystalline substrate layer 10. Each semiconductor fin 30 in the first device region 100 includes a center portion that overlies the recessed region. The single crystalline semiconductor material of the semiconductor fins 30 is lattice-mismatched with respect to the single crystalline substrate layer 20.

The center portion of each semiconductor fin 30 in the first device region 100 is vertically spaced from a recessed surface of the recessed region. The gate dielectric 50 is formed directly on at least a portion of the recessed surface of the recessed region, and directly on sidewall surfaces, a top surface, and a bottom surface of each of the at least one semiconductor fin 30. The entirety of the gate dielectric 50 can be formed as a single contiguous structure that includes at least one hole therein. Each center portion of the at least one semiconductor fin passes through one of the at least one hole.

The gate electrode 52 is formed between the recessed surface of the recessed region and the bottom surface of each of the at least one semiconductor fin 30, and over and around each of the at least one semiconductor fin 30. Thus, the gate electrode 50 includes a portion located between the recessed surface of the recessed region and the bottom surface of each semiconductor fin 30. The entirety of the gate electrode 52 can be a single contiguous structure that includes at least one hole therein. The center portion of each semiconductor fin 30 passes through one of the at least one hole.

The gate dielectric 50 contacts at least a portion of the recessed surface of the recessed region, sidewall surfaces of the center portion of each semiconductor fin 30, a top surface of the center portion of each semiconductor fin 30, and a bottom surface of the center portion of each semiconductor fin 30.

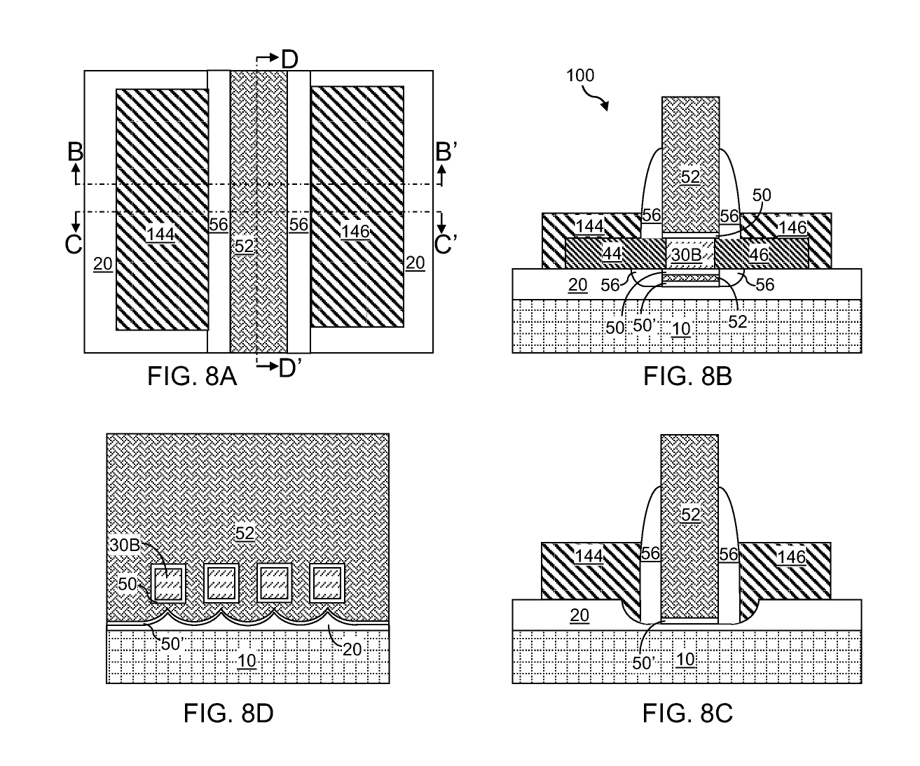

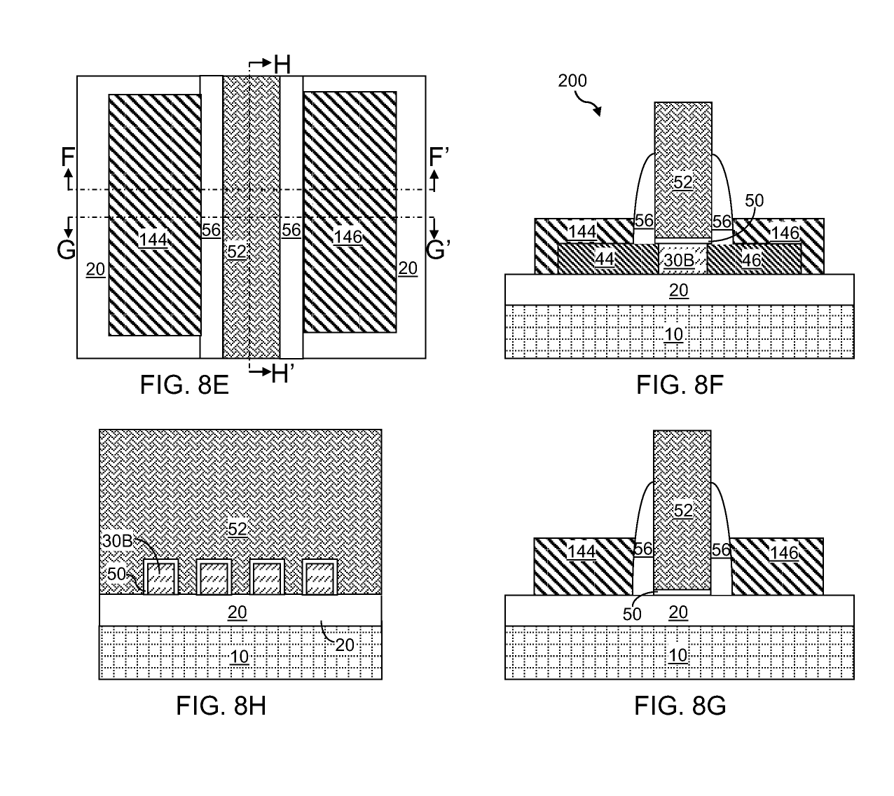

Referring to FIGS. 8A-8H, various source regions 44 and drain regions 46, gate spacers 56, optional raised source regions 144, and optional raised drain regions 146 can be formed. FIGS. 8A-8D show various views of the first device region 100, and FIGS. 8E-8H show various views of the second device region 200. A first field effect transistor is formed in the first device region 100, and a second field effect transistor is formed in the second device region 200.

Specifically, source regions 44 and drain regions 46 are formed in the first and second device regions (100, 200) by implantation of dopant ions employing the gate electrodes 52 as self-aligned implantation mask layer. An additional implantation mask layer, such as a patterned photoresist layer overlying an entirety of the first device region 100 or overlying an entirety of the second device region 200, can be employed to provide desired types and levels of implanted dopant ions into each of the source regions 44 and the drain regions 46. A source region 44 is formed in each first end portion of the semiconductor fins 30, and a drain region is formed in each second end portion of the semiconductor fins 30. The center portion of each semiconductor fin 30 constitutes a body region 30B, which function as a body region of a field effect transistor.

The gate spacers 56 are formed on sidewalls of the gate electrodes 52, for example, by deposition of a conformal dielectric material layer and an anisotropic etch that removes horizontal portions of the conformal dielectric material layer. The remaining vertical portions of the conformal dielectric material layer constitute the gate spacers 56. Each gate spacer 56 is formed around a gate electrode 52, and directly on portions of the recessed surface of the recessed region.

The raised source regions 144 and the raised drain regions 146 can be optionally formed, for example, by epitaxy of a source/drain material on physically exposed surfaces of the source regions 44 and the drain regions 46. In one embodiment, the raised source regions 144 and the raised drain regions 146 can be formed as intrinsic semiconductor material portions, and can be subsequently doped, for example, by ion implantation. In another embodiment, the raised source regions 144 and the raised drain regions 146 can be formed with in-situ doping. Optionally, at least one disposable hard mask layer can be employed to enable formation of a subset of the raised source regions 144 and the raised drain regions 146 with in-situ doping of a first conductivity type, and subsequent formation of another subset of the raised source regions 144 and the raised drain regions 146 with in-situ doping of a second conductivity type which is the opposite of the first conductivity type. Each raised source region 144 is epitaxially aligned to each of the at least one underlying source region 44, and each raised drain region 146 is epitaxially aligned to each of the at least one underlying drain region 46.

The entirety of each semiconductor fin 30 can have the same vertical cross-sectional shape within vertical planes that are perpendicular to the lengthwise direction of the semiconductor fin 30. In one embodiment, the first and second end portions of each semiconductor fin 30 in the first device region 100 are under the first type of stress along the lengthwise direction of the semiconductor fin 30, and the center portion of each semiconductor fin 30 can be under the second type of stress that is the opposite of the first type of stress. In one embodiment, the first type of stress can be a compressive stress and the second type of stress can be a tensile stress. In another embodiment, the first type of stress can be a tensile stress and the second type of stress can be a compressive stress. In one embodiment, the raised source region 144 in the first device region 100 and the raised drain region 146 in the first device region 100 can contact a portion of the recessed surface of the recessed region.

The first field effect transistor in the first device region 100 includes a body region 30B including the center portion of a semiconductor fin 30 and having a doping of the first conductivity type, a source region 44 including the first end portion of the semiconductor fin 30 and having a doping of the second conductivity type that is the opposite of the first conductivity type, and a drain region 46 including the second end portion of the semiconductor fin 30 and having the doping of the second conductivity type.

The second field effect transistor in the second device region 200 includes a body region 30B, a source region 44, and a drain region within each of the semiconductor fin 30 located on the single crystalline substrate layer 20 and in the second device region 200. The entirety of the bottom surfaces of the at least one semiconductor fin 30 in the second device region 200 contacts, and is epitaxially aligned to, the single crystalline substrate layer 10. The entirety of the at least one semiconductor fin 30 in the second device region 200 is under the first type of stress along the lengthwise direction of the at least one semiconductor fin 30 in the second device region because of the epitaxial registry of the active material of the at least one semiconductor fin 30 to the virtual substrate material of the single crystalline substrate layer 10 and due to the lattice mismatch between the virtual substrate material and the active material.

In one embodiment, of the first field effect transistor and the second field effect transistor can be a p-type field effect transistor, and the other of the first field effect transistor and the second field effect transistor can be an n-type field effect transistor.

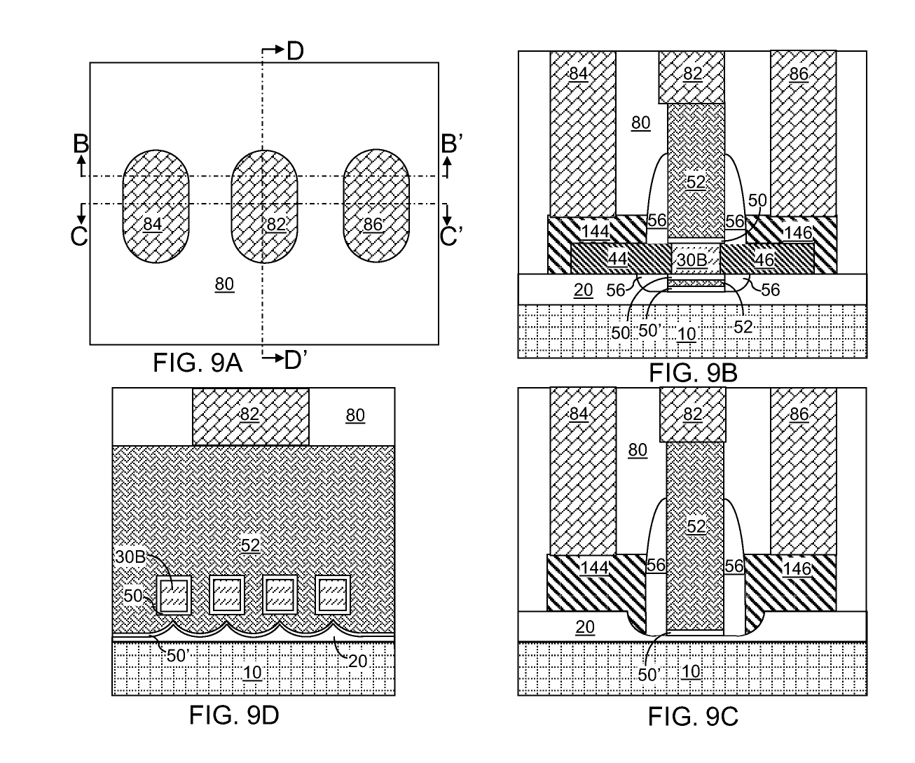

Referring to FIGS. 9A-9D, a contact level dielectric layer 80 and various contact via structures (82, 84, 86) can be formed to provide electrical contact to the source region 44, the drain region 46, and the gate electrode 52 of each field effect transistor.

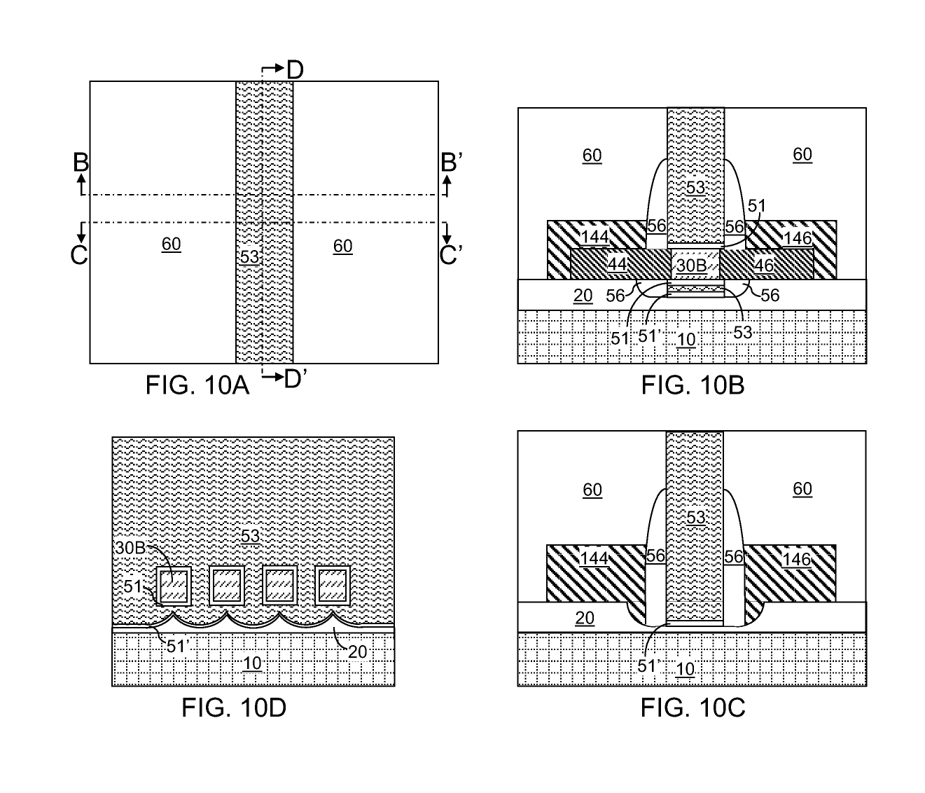

Referring to FIGS. 10A-10D, a second exemplary semiconductor structure according to an embodiment of the present disclosure is derived from the first exemplary structure by substituting a combination of a disposable gate dielectric 51 and a disposable gate structure 53 for each combination of a gate dielectric 52 and a gate electrode 54 in the first device region 100 and in the second device region 200. Each combination of a gate dielectric 52 and a gate electrode 54 is herein referred to as a disposable gate stack (51, 53). Specifically, at the processing steps corresponding to FIGS. 7A-7D, the combination of a disposable gate dielectric 51 and a disposable gate structure 53 is formed over each center portion of the at least one semiconductor fin 30 in the first device region 100 and in the second device region 200. After the processing steps of FIGS. 8A-8H, a planarization dielectric material is deposited and planarized over the disposable gate structures 53 and the gate spacer 56 to form a planarization dielectric layer 60. The planarization dielectric layer 60 can include silicon oxide, silicon nitride, silicon oxynitride, organosilicate glass, or other dielectric materials known in the art.

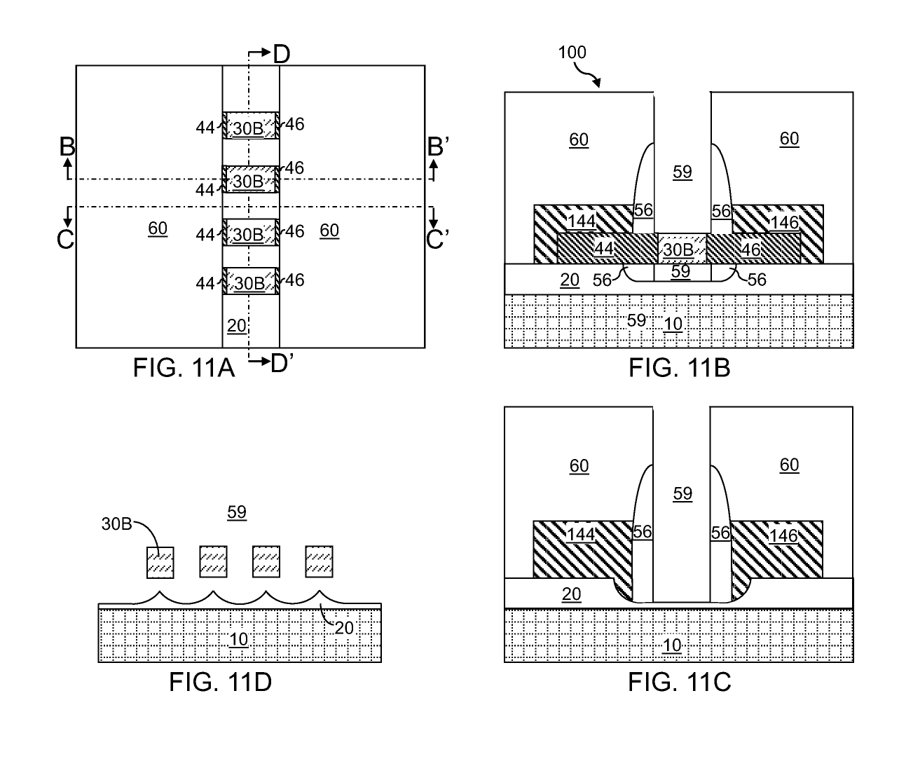

Referring to FIGS. 11A-11D, the disposable gate stacks (51, 53) are removed from the first and second device regions (100, 200) to form gate cavities 59. The removal of the disposable gate structure 53 can be performed selective to the material of the planarization dielectric layer 60 and the material of the disposable gate dielectrics 51. Subsequently, the disposable gate dielectrics 51 can be removed.

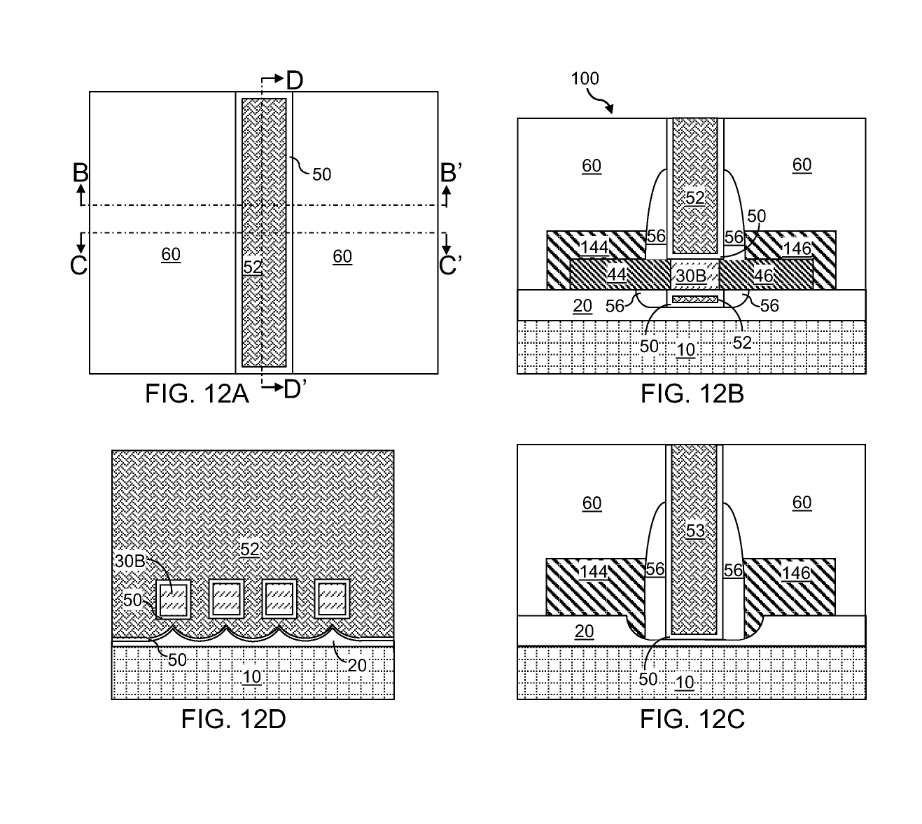

Referring to FIGS. 12A-12D, replacement gate structures (50, 52) are formed within the gate cavities 59, for example, by deposition of a gate dielectric layer and a gate electrode layer within the gate cavities 59, and by subsequent removal of the portions of the gate dielectric layer and the gate electrode layer from above the top surface of the planarization dielectric layer 60 by planarization. Recess etch, chemical mechanical planarization (CMP), or a combination thereof can be employed to remove the portions of the gate dielectric layer and the gate electrode layer from above the top surface of the planarization dielectric layer 60.

The gate dielectric 50 in the first device region 100 is formed directly on at least a portion of the recessed surface of the recessed region, and directly on sidewall surfaces, a top surface, and a bottom surface of each of the at least one semiconductor fin 30 in the first device region 100. The entirety of the gate dielectric 50 can be formed as a single contiguous structure that includes at least one hole therein. Each hole corresponds to one of the at least one semiconductor fin 30 that is laterally surrounded by the gate electric 50. Specifically, each center portion of the at least one semiconductor fin 30 passes through one of the at least one hole.

The single crystalline substrate layer 20 includes the recessed region that is recessed relative to the top surface of the single crystalline substrate layer 20 within the first device region. Each semiconductor fin 30 in the first device region 100 includes a single crystalline semiconductor material (which is the active material) and includes first and second end portions, which are in contact with the top surface of the single crystalline substrate layer 10 and are epitaxially aligned to the single crystalline substrate layer 10. Each semiconductor fin 30 in the first device region 100 includes a center portion that overlies the recessed region. The single crystalline semiconductor material of the semiconductor fins 30 is lattice-mismatched with respect to the single crystalline substrate layer 10.

The center portion of each semiconductor fin 30 in the first device region 100 is vertically spaced from a recessed surface of the recessed region. The gate dielectric 50 is formed directly on at least a portion of the recessed surface of the recessed region, and directly on sidewall surfaces, a top surface, and a bottom surface of each of the at least one semiconductor fin 30. The entirety of the gate dielectric 50 can be formed as a single contiguous structure that includes at least one hole therein. Each center portion of the at least one semiconductor fin passes through one of the at least one hole.

The gate electrode 52 is formed between the recessed surface of the recessed region and the bottom surface of each of the at least one semiconductor fin 30, and over and around each of the at least one semiconductor fin 30. Thus, the gate electrode 50 includes a portion located between the recessed surface of the recessed region and the bottom surface of each semiconductor fin 30. The entirety of the gate electrode 52 can be a single contiguous structure that includes at least one hole therein. The center portion of each semiconductor fin 30 passes through one of the at least one hole.

The gate dielectric 50 contacts at least a portion of the recessed surface of the recessed region, sidewall surfaces of the center portion of each semiconductor fin 30, a top surface of the center portion of each semiconductor fin 30, and a bottom surface of the center portion of each semiconductor fin 30.

The entirety of each semiconductor fin 30 can have the same vertical cross-sectional shape within vertical planes that are perpendicular to the lengthwise direction of the semiconductor fin 30. In one embodiment, the first and second end portions of each semiconductor fin 30 in the first device region 100 are under the first type of stress along the lengthwise direction of the semiconductor fin 30, and the center portion of each semiconductor fin 30 can be under the second type of stress that is the opposite of the first type of stress. In one embodiment, the first type of stress can be a compressive stress and the second type of stress can be a tensile stress. In another embodiment, the first type of stress can be a tensile stress and the second type of stress can be a compressive stress. In one embodiment, the raised source region 144 in the first device region 100 and the raised drain region 146 in the first device region 100 can contact a portion of the recessed surface of the recessed region.

The first field effect transistor in the first device region 100 includes a body region 30B including the center portion of a semiconductor fin 30 and having a doping of the first conductivity type, a source region 44 including the first end portion of the semiconductor fin 30 and having a doping of the second conductivity type that is the opposite of the first conductivity type, and a drain region 46 including the second end portion of the semiconductor fin 30 and having the doping of the second conductivity type.

The second field effect transistor in the second device region 200 includes a body region 30B, a source region 44, and a drain region within each of the semiconductor fin 30 located on the single crystalline substrate layer 20 and in the second device region 200. The entirety of the bottom surfaces of the at least one semiconductor fin 30 in the second device region 200 contacts, and is epitaxially aligned to, the single crystalline substrate layer 10. The entirety of the at least one semiconductor fin 30 in the second device region 200 is under the first type of stress along the lengthwise direction of the at least one semiconductor fin 30 in the second device region because of the epitaxial registry of the active material of the at least one semiconductor fin 30 to the virtual substrate material of the single crystalline substrate layer 10 and due to the lattice mismatch between the virtual substrate material and the active material.

In one embodiment, of the first field effect transistor and the second field effect transistor can be a p-type field effect transistor, and the other of the first field effect transistor and the second field effect transistor can be an n-type field effect transistor.

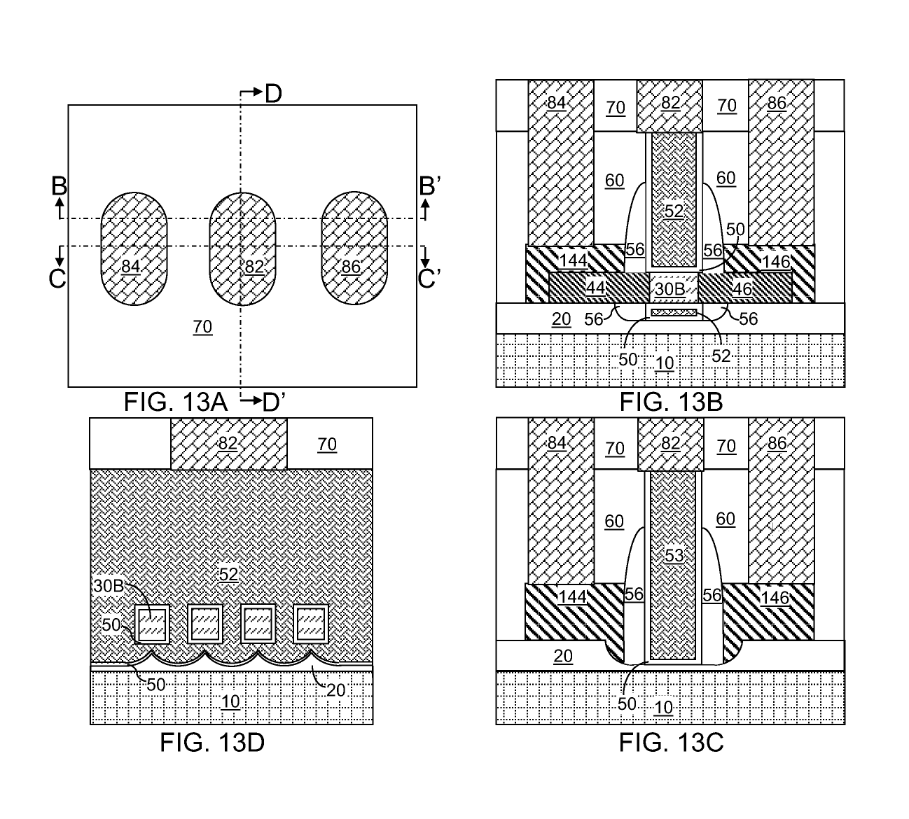

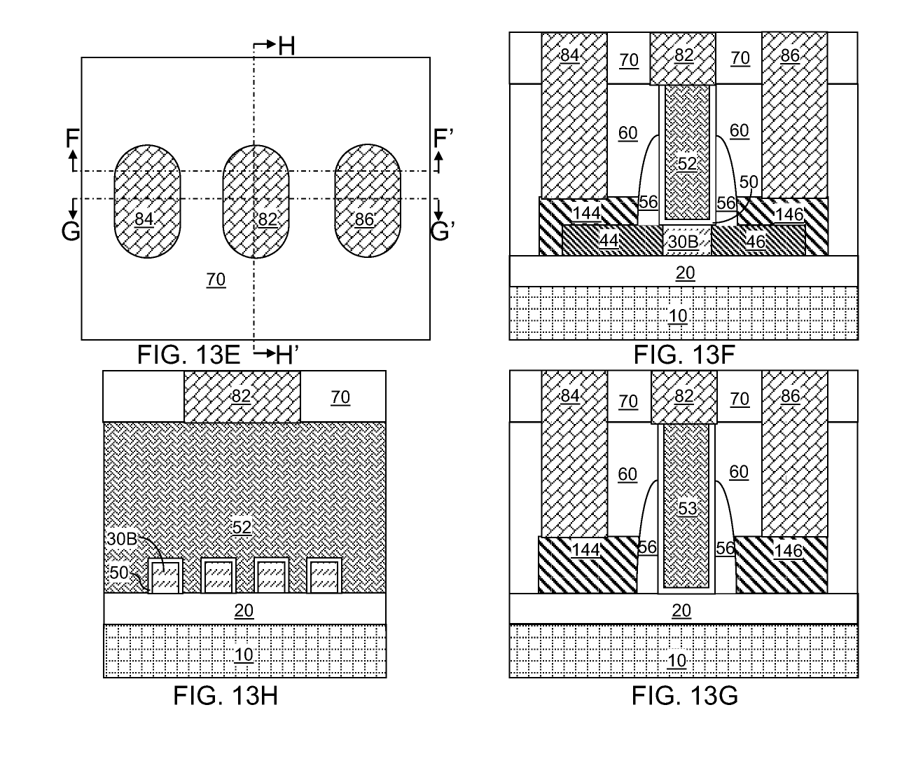

Referring to FIGS. 13A-13H, a contact level dielectric layer 70 and various contact via structures (82, 84, 86) can be formed. FIGS. 13A-13D show various views of the first device region 100, and FIGS. 13E-13H show various views of the second device region 200.

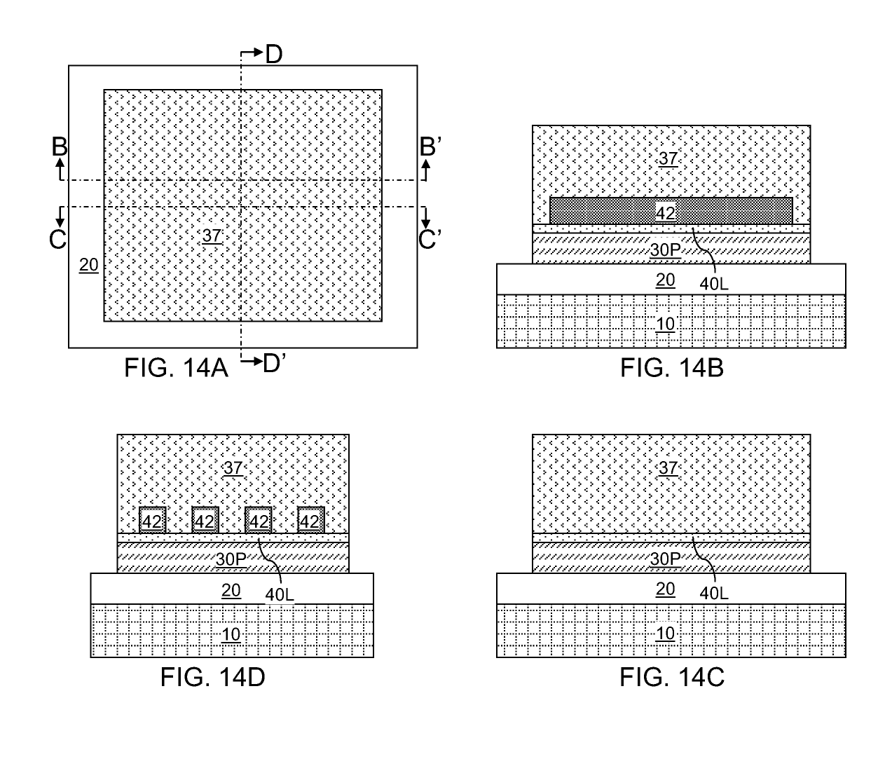

Referring to FIGS. 14A-14D, a selected region of a third exemplary semiconductor structure is shown, which can be derived from the first exemplary semiconductor structure illustrated in FIGS. 1A and 1B. The selected region can be the first device region 100 or the second device region 200. The same processes are performed to the first device region 100 and to the second device region 200. Thus, the first device region 100 and the second device region 200 can have the same structure. The epitaxial semiconductor layer 30L is patterned to form an epitaxial semiconductor portion 30P in each of the first device region 100 and the second device region 200.

The epitaxial semiconductor portions 30P in the first and second device regions (100, 200) can be formed, for example, by application of a photoresist layer 37 over the plurality of fin-defining mask structures 42 and the epitaxial semiconductor layer 30L, and by lithographically patterning the photoresist layer 37 so that each set of the at least one fin-defining mask structure 42 in the first device region 100 or in the second device region 200 are completely covered by the patterned photoresist layer 37. The pattern in the photoresist layer 37 is transferred through the optional dielectric liner layer 40L and the epitaxial semiconductor layer 30L so that an epitaxial semiconductor portion 30P replicating a shape of a portion of the photoresist layer 37 is formed in each of the first and second device regions (100, 200).

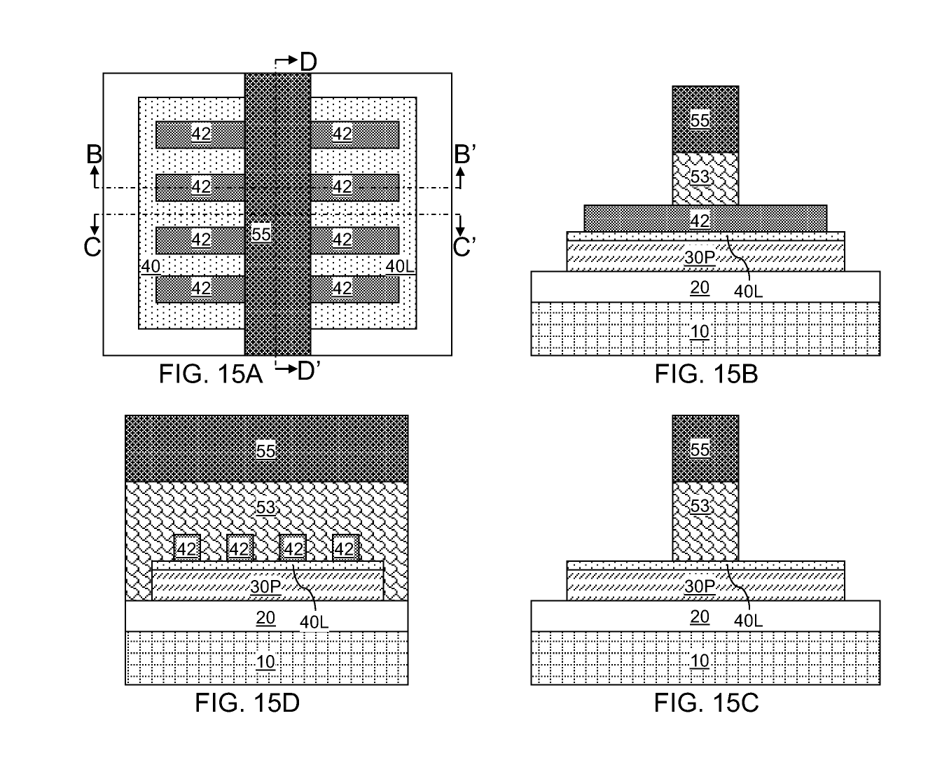

Referring to FIGS. 15A-15D, a disposable gate structure 53 and a disposable gate cap 55 can be formed in each of the first and second device regions (100, 200). The disposable gate structures 53 and the disposable gate caps 55 can be formed, for example, by depositing a disposable gate material layer (not shown) and a disposable gate cap layer (not shown), and subsequently lithographically patterning the disposable gate material layer and the disposable gate cap layer. Each remaining portion of the disposable gate material layer after the lithographic patterning constitutes a disposable gate structure 53, and each remaining portion of the disposable gate cap layer after the lithographic patterning constitutes a disposable gate cap 55.

The disposable gate material layer includes a material that can be removed selective to the material of the plurality of fin-defining mask structures 42 and selective to material of the optional dielectric liner layer 40L if the optional dielectric liner layer 40L is present. In this case, the disposable gate material layer can include a semiconductor material, a dielectric material that is different from the dielectric material of the optional dielectric cap pad layer 40L, or a metallic material. Exemplary semiconductor materials that can be employed for the disposable gate material layer include silicon, germanium, a silicon germanium alloy, a silicon carbon alloy, a compound semiconductor material, or a combination thereof. The disposable gate material layer can be deposited, for example, by chemical vapor deposition (CVD). The thickness of the disposable gate material layer, as measured above a planar surface, can be from 50 nm to 600 nm, although lesser and greater thicknesses can also be employed.

The disposable gate material layer includes a material that can be removed selective to the material of the plurality of fin-defining mask structures 42 and selective to the material of the epitaxial semiconductor portions 30P if the optional dielectric liner layer 40L is not present. In this case, the disposable gate material layer can include a semiconductor material that is different from the active material (i.e., the semiconductor material of the epitaxial semiconductor portions 30P), a dielectric material, or a metallic material. Exemplary semiconductor materials that can be employed for the disposable gate material layer include silicon, germanium, a silicon germanium alloy, a silicon carbon alloy, a compound semiconductor material, or a combination thereof. The disposable gate material layer can be deposited, for example, by chemical vapor deposition (CVD). The thickness of the disposable gate material layer, as measured above a planar surface, can be from 50 nm to 600 nm, although lesser and greater thicknesses can also be employed. In one embodiment, the active material can be In_{y}Ga_{(1-y)}As, and the material of the disposable gate material layer can be silicon, germanium, a silicon germanium alloy, undoped silicon oxide, doped silicon oxide, or a combination thereof.

The disposable gate cap layer includes a material that can be employed as mask to block subsequent processes such as epitaxial growth or silicide from affecting the disposable gate stack. For example, the disposable gate cap layer can include silicon nitride, silicon oxide, silicon oxynitride, or a combination thereof. The thickness of the disposable gate cap layer can be from 20 nm to 300 nm, although lesser and greater thicknesses can also be employed. In one embodiment, the disposable gate cap layer can include the same material as the material of the plurality of fin-defining mask structures 42. In this case, the thickness of the disposable gate cap layer can be greater than the height (thickness) of the plurality of fin-defining mask structures 42. In one embodiment, the plurality of fin-defining mask structures 42 and the disposable gate cap layer can include silicon nitride.

A photoresist layer (not shown) can be applied over the stack, from bottom to top, of the disposable gate material layer and the disposable gate cap layer. The photoresist layer can be subsequently patterned into gate patterns, which are typically a plurality of lines which run perpendicular to and intersect the plurality of fin-defining mask structures 42. Physically exposed portions of the disposable gate material layer and the disposable gate cap layer, i.e., portions of the disposable gate material layer and the disposable gate cap layer that are not covered by the patterned photoresist layer, are removed, for example, by an etch, which can be an anisotropic etch. The etch that removes physically exposed portions of the disposable gate material layer and the disposable gate cap layer can be selective to the materials of the plurality of fin-defining mask structures 42. If the optional dielectric liner layer 40L is present, the etch that removes physically exposed portions of the disposable gate material layer and the disposable gate cap layer can be selective to the materials of the optional dielectric liner layer 40. If the optional dielectric liner layer 40L is not present, the etch that removes physically exposed portions of the disposable gate material layer and the disposable gate cap layer can be selective to the active material of the epitaxial semiconductor portions 30P. The stack of the disposable gate structure 53 and the disposable gate cap 55 straddles over middle portions of the plurality of fin-defining mask structures 42.

Each disposable gate structure 53 is formed over and across the at least one fin-defining mask structure 42. In one embodiment, the portions of the epitaxial semiconductor portions 30P that do not underlie the stack of the disposable gate structure 53 and the disposable gate cap 55 can be doped with dopants to form a source region (not shown) and a drain region (not shown).

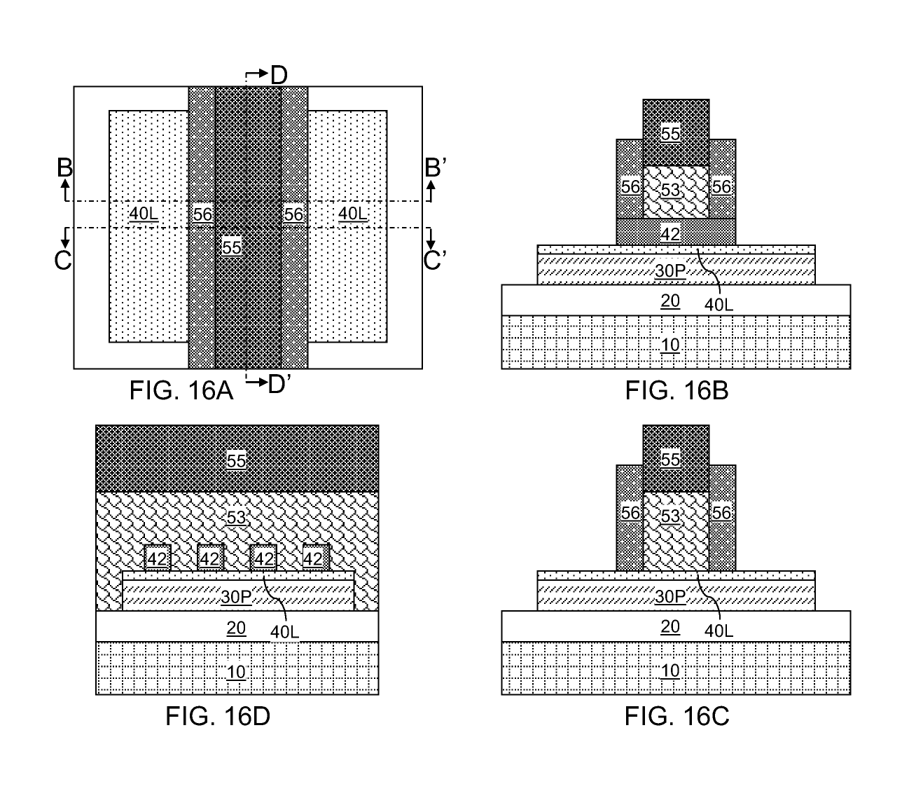

Referring to FIGS. 16A-16D, a gate spacer 56 can be formed on sidewalls of each stack of a disposable gate structure 53 and a disposable gate cap 55. A conformal dielectric material layer (not shown) can be deposited on the stacks of the disposable gate structure 53 and the disposable gate cap 55 and over the plurality of fin-defining mask structures 42, for example, by chemical vapor deposition (CVD) or atomic layer deposition (ALD). The conformal dielectric material layer includes a dielectric material such as silicon nitride, silicon oxide, a dielectric metal oxide, or a combination thereof. The thickness of the conformal dielectric material layer can be from 3 nm to 100 nm, although lesser and greater thicknesses can also be employed.

The dielectric material of the conformal dielectric material layer may, or may not be, the same as the dielectric material of the plurality of fin-defining mask structures 42. In one embodiment, the dielectric material of the conformal dielectric material layer can be the same as the dielectric material of the plurality of fin-defining mask structures 42. In one embodiment, the dielectric material of the conformal dielectric material layer and the dielectric material of the plurality of fin-defining mask structures 42 can be silicon nitride.

Vertical portions of the conformal dielectric material layer are subsequently etched by an anisotropic etch to form the gate spacers 56. The anisotropic etch that forms the gate spacers 56 can be selective to the material of the optional dielectric liner layer 40L if the optional dielectric liner layer 40L is present. The anisotropic etch that forms the gate spacers 56 can be selective to the active material of the epitaxial semiconductor portions 30P if the optional dielectric liner layer 40L is not present. Each gate spacer 56 is formed over and across the at least one fin-defining mask structure 42. Each gate spacer 56 can have a bottommost surface that is located at or above the topmost surfaces of the semiconductor fins 30.

Further, portions of the plurality of fin-defining mask structures 42 that are not covered by the disposable gate structures 53 or by vertical portions of the conformal dielectric material layer, i.e., the portions of the conformal dielectric material layer that become the gate spacer 56, are etched by a subsequent etch, which may employ the same etch chemistry as the etch that forms the gate spacer 56, or may employ a different etch chemistry. The subsequent etch can be selective to the material of the optional dielectric liner layer 40L if the optional dielectric liner layer 40L is present. The subsequent etch can be selective to the active material of the epitaxial semiconductor portions 30P if the optional dielectric liner layer 40L is not present. The subsequent etch can be an anisotropic etch, or can be an isotropic etch. Thus, portions of the plurality of fin-defining mask structures 42 that are not covered by the disposable gate structure 53 or by the gate spacer 56 are removed by the end of the subsequent etch.

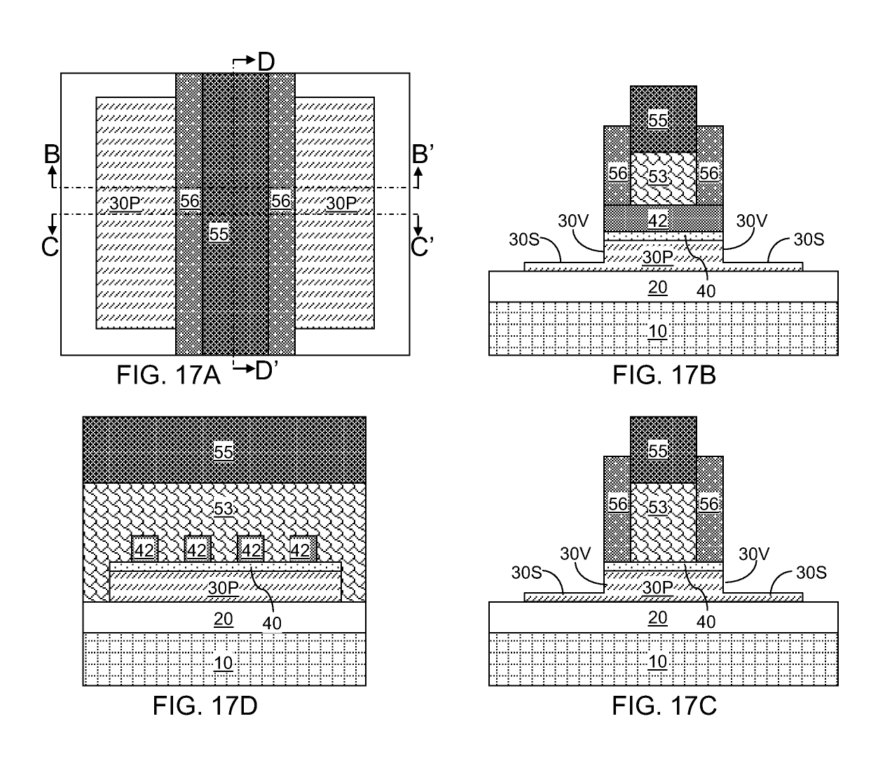

Referring to FIGS. 17A-17D, portions of the optional dielectric liner layer 40L can be removed by an etch, which can be an anisotropic etch or an isotropic etch. Each remaining portion of the optional dielectric liner layer 40L is herein referred to as an optional dielectric liner 40. Each optional dielectric liner 40 underlies a plurality of fin-defining mask structures 42, a disposable gate structure 53, and a gate spacer 56.

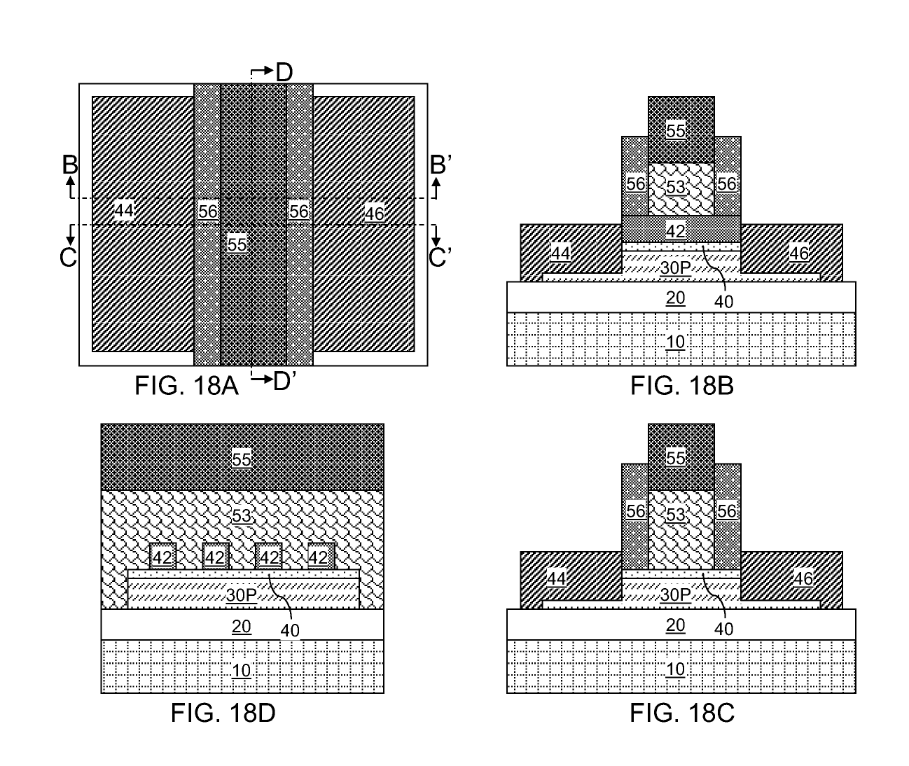

Subsequently, portions of the patterned epitaxial semiconductor portion 30P that are not covered by the disposable gate structure 53 or by the gate spacer 56 may be optionally recessed, and different source/drain materials regrown in replacement. See FIGS. 17A-17D and FIGS. 18A-18D.

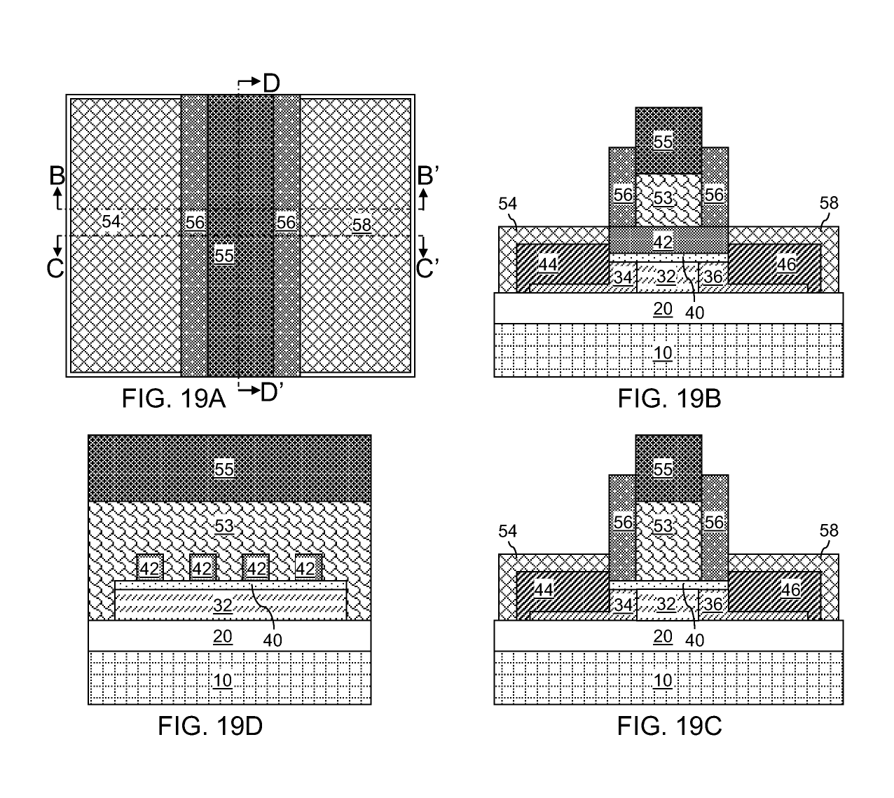

Referring to FIGS. 19A-19D, a source region 34 and a drain region 36 can be formed in each of the first and second device regions (100, 200), for example, by diffusing dopants from the first and second stress-generating semiconductor portions (44, 46) into the each epitaxial semiconductor portion 30P. The portion of each patterned epitaxial semiconductor layer 30P having a doping of the opposite conductivity type from the doping of the source region 34 and the drain region 36 within the same epitaxial semiconductor portion 30P constitute a contiguous body portion 32. A p-n junction is formed between a source region 34 and a contiguous body portion 32 within an epitaxial semiconductor portion 30P in each device region (100, 200). Another p-n junction is formed between a drain region 36 and the contiguous body portion 32 within an epitaxial semiconductor portion 30P in each device region (100, 200).

Various metal semiconductor alloy portions (54, 58) can be formed on the physically exposed semiconductor surfaces of the first stress-generating semiconductor portion 44 and the second stress-generating semiconductor portion 46. For example, the various metal semiconductor alloy portions (54, 58) can be formed by depositing a metal layer by physical vapor deposition (PVD) or chemical vapor deposition (CVD), and by reacting the metal layer with the underlying active material at an elevated temperature, and subsequently removing unreacted portions of the metal layer. The various metal semiconductor alloy portions (54, 58) can include a first metal semiconductor alloy portion 54 that is formed on the first stress-generating semiconductor portion 44, and a second metal semiconductor alloy portion 58 that is formed on the second stress-generating semiconductor portion 46. If the first and second metal semiconductor alloy portions (54, 58) include silicon or a silicon-containing alloy, the first and second metal semiconductor alloy portions (54, 58).

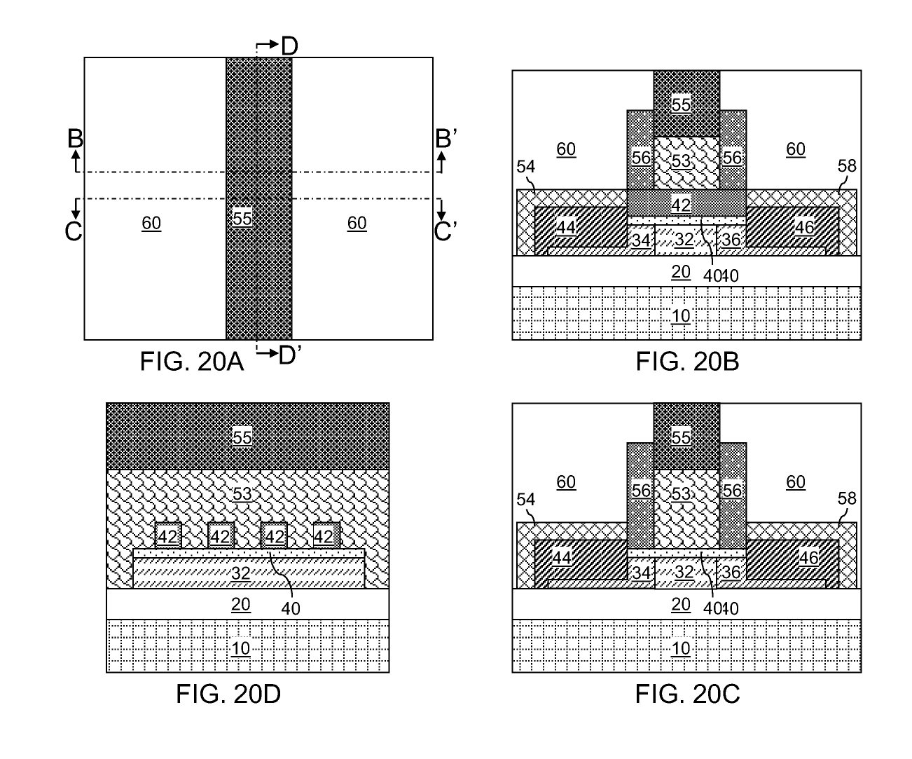

Referring to FIGS. 20A-20D, a planarization dielectric layer 60 can be deposited over the disposable gate cap 55, the gate spacer 56, and the various metal semiconductor alloy portions (54, 58). The planarization dielectric layer 60 includes at least one dielectric material, which can be silicon oxide, silicon nitride, silicon oxynitride, organosilicate glass (OSG), or a combination thereof. The thickness of the planarization dielectric layer 60 can be selected so that the entirety of the top surface of the planarization dielectric layer 60 is formed above the top surface of the disposable gate cap 55.

The planarization dielectric layer 60 can be subsequently planarized, for example, by chemical mechanical planarization (CMP) and/or a recess etch. In one embodiment, the disposable gate cap 55 can be employed as a stopping layer.

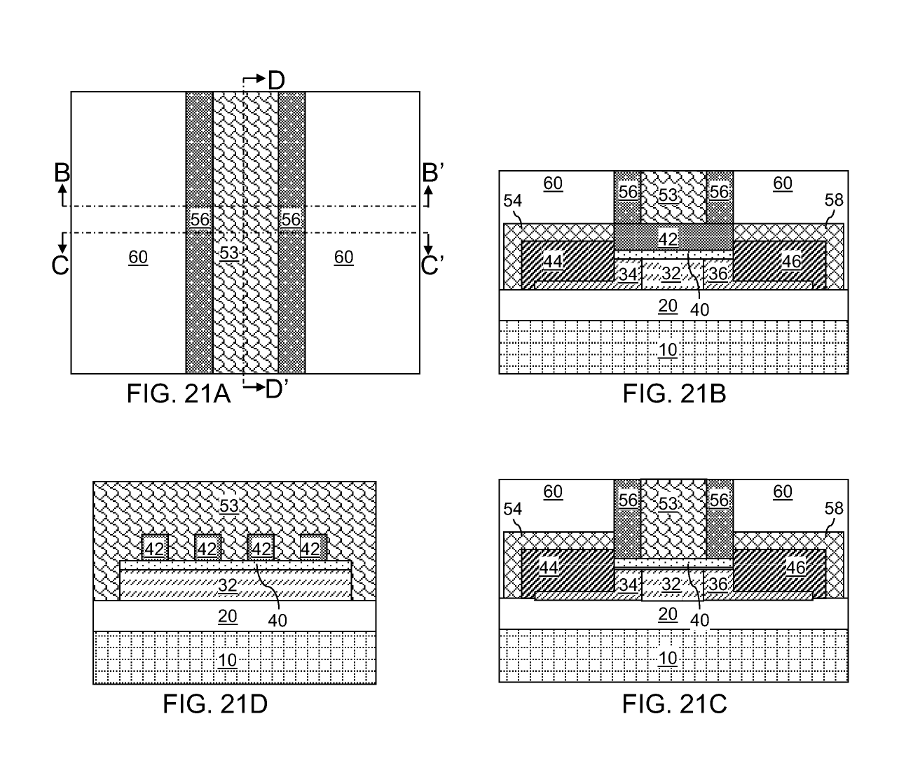

Referring to FIGS. 21A-21D, additional portions of the planarization dielectric layer 60 and the disposable gate cap 55 can be removed by an additional planarization process, which can be performed by additional CMP and/or an additional recess etch. In one embodiment, the disposable gate structure 53 can be employed as a stopping layer. A top surface of the disposable gate structure 53 is physically exposed. The top surface of the planarization dielectric layer 60 can be a planar surface.

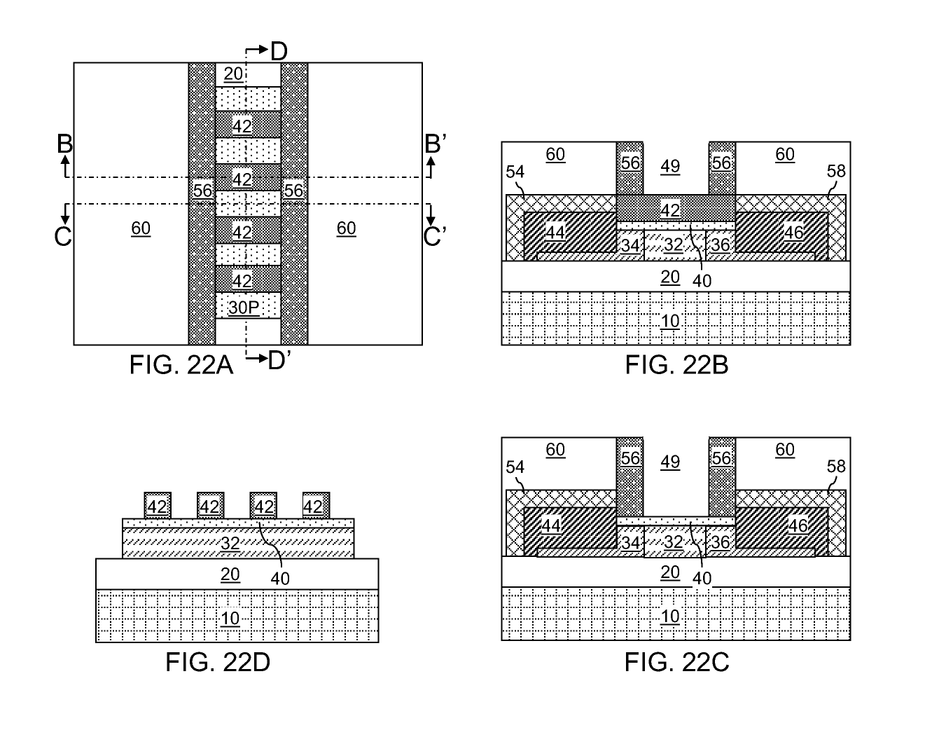

Referring to FIGS. 22A-22D, the disposable gate structures 53 can be removed selective to the plurality of fin-defining mask structures 42 in each of the first device region 100 and the second device region 200. If the optional dielectric liner 40 is present, the disposable gate structures 53 can be removed selective to material of the optional dielectric liner 40. If the optional dielectric liner 40 is not present, the disposable gate structures 53 can be removed selective to the active material of the plurality of fin-defining mask structures 42. A gate cavity 49 is formed within a volume from which the disposable gate structure 53 is removed in each of the first and second device regions (100, 200).

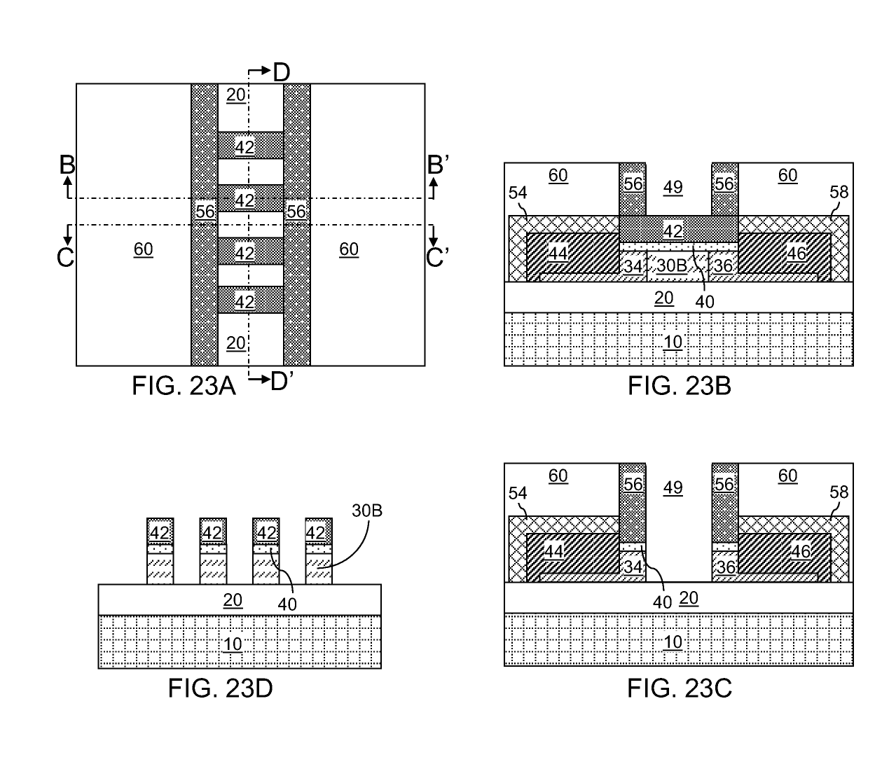

Referring to FIGS. 23A-23D, at least one semiconductor fin can be formed by transfer of the pattern of the at least one fin-defining mask structure 42 underneath the gate cavity 49 into the patterned epitaxial semiconductor portion 30P in each of the first device region 100 and the second device region 200. If the at least one fin-defining mask structure 42 is a plurality of fin-defining mask structures 42, the at least one semiconductor fin is a plurality of semiconductor fins. The area of the plurality of semiconductor fins is the intersection of the area of the plurality of fin-defining mask structures 42 and the area of the gate cavity 49 (which is the same as the area of the disposable gate structures 53) in each of the first and second device regions (100, 200). The remaining portions of the contiguous body portion 32 constitutes at least one body region 30B.

The remaining portions of each epitaxial semiconductor portion 30P constitute a fin-containing semiconductor structure (34, 30B, 36). Each fin-containing semiconductor structure includes the active material. In one embodiment, the fin-containing semiconductor structure 30 can include a plurality of semiconductor fins containing the body regions 30B, a first end portion containing a source region 34, and a second end portion containing a drain region 36. Each semiconductor fin among the plurality of semiconductor fins is laterally spaced from each other or one another along a widthwise direction, which is perpendicular to the lengthwise direction of the plurality of semiconductor fins. The lengthwise direction of the plurality of semiconductor fins is the same as the lengthwise direction of the plurality of fin-defining mask structures 42. In one embodiment, the first stress-generating semiconductor portion 44 functions as an extended source region, and the second stress-generating semiconductor portion 46 functions as an extended drain region.

In one embodiment, a plurality of fin-defining mask structures 42 overlies the plurality of semiconductor fins, and the plurality of semiconductor fins has a same width as the plurality of fin-defining mask structures 42. In one embodiment, the gate spacer 56 can contact the first and second stress-generating semiconductor portions (44, 46) within each of the first device region 100 and the second device region 200.

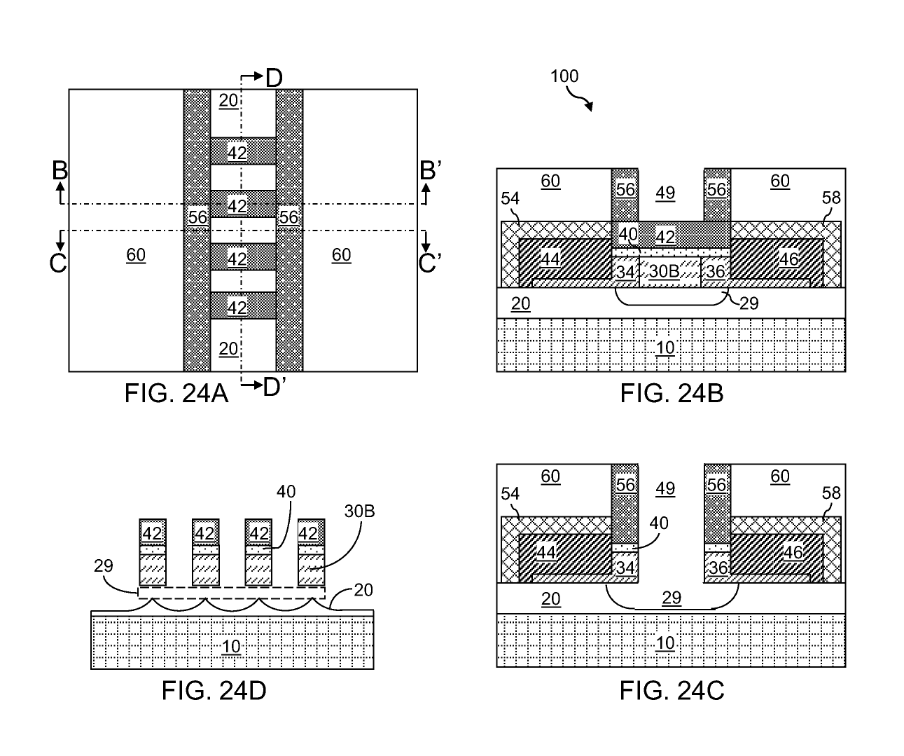

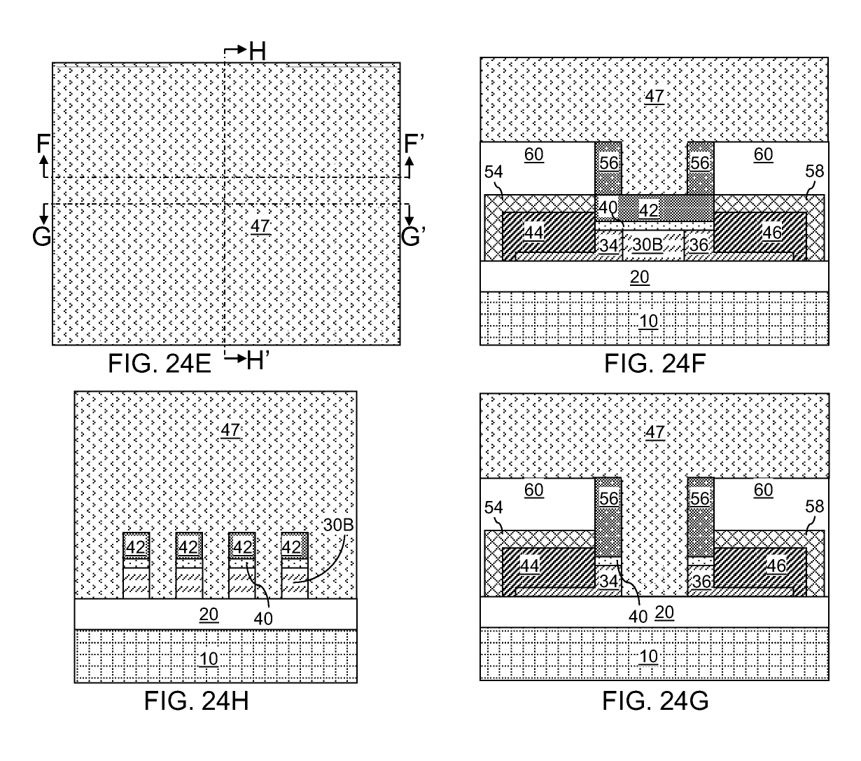

Referring to FIGS. 24A-24H, the virtual substrate material in physically exposed portions of the single crystalline substrate layer 20 are removed by an isotropic etch selective to the active material. The isotropic etch can be a wet etch or a dry etch. The chemistry of the isotropic etch is selected such that the virtual substrate material is etched selective to the active material, i.e., without significantly etching the active material. The same etch process can be employed as the etch process employed in the processing steps of FIGS. 5A-5H can be employed.

A recessed region 29 is formed in the single crystalline substrate layer 20 underneath center portions of the at least one semiconductor fin in the first device region 100. A first end portion and a second end portion of each of the at least one semiconductor fin remains in contact with the top surface of the single crystalline substrate layer 20, and a center portion of each of the at least one semiconductor fin within the first device region 100 overlies the recessed region 29.

The first and second end portions of each of the at least one semiconductor fin are under the first type of stress due to epitaxial registry of the active material to the virtual substrate material in the single crystalline substrate layer 20 and due to the lattice mismatch between the active material and the virtual substrate material. Because the center portion of each semiconductor fin within the first device region 100 is not epitaxially aligned to the single crystalline substrate layer 20, the center portion of each semiconductor fin in the first device region can be under a second type of stress that is the opposite of the first type of stress along the lengthwise direction of the semiconductor fin. In one embodiment, the first type of stress can be compressive stress and the second type of stress can be tensile stress. In another embodiment, the first type of stress can be tensile stress and the second type of stress can be compressive stress.

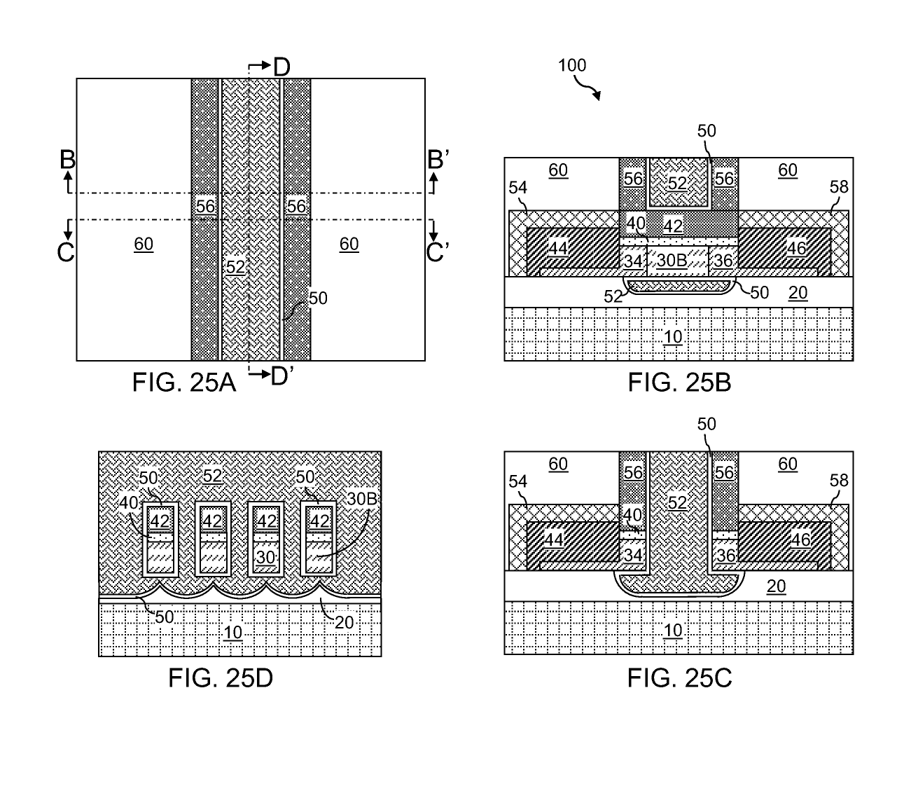

Referring to FIGS. 25A-25D, replacement gate structures (50, 52) are formed within the gate cavities 59, for example, by deposition of a gate dielectric layer and a gate electrode layer within the gate cavities 59, and by subsequent removal of the portions of the gate dielectric layer and the gate electrode layer from above the top surface of the planarization dielectric layer 60 by planarization. Recess etch, chemical mechanical planarization (CMP), or a combination thereof can be employed to remove the portions of the gate dielectric layer and the gate electrode layer from above the top surface of the planarization dielectric layer 60.

The gate dielectric 50 in the first device region 100 is formed directly on the entirety of the recessed surface of the recessed region, and directly on sidewall surfaces, a top surface, and a bottom surface of each of the at least one semiconductor fin in the first device region 100. The entirety of the gate dielectric 50 can be formed as a single contiguous structure that includes at least one hole therein. Each hole corresponds to one of the at least one semiconductor fin that is laterally surrounded by the gate electric 50. Specifically, each center portion of the at least one semiconductor fin passes through one of the at least one hole.

The single crystalline substrate layer 20 includes the recessed region that is recessed relative to the top surface of the single crystalline substrate layer 20 within the first device region. Each semiconductor fin in the first device region 100 includes a single crystalline semiconductor material (which is the active material) and includes first and second end portions, which are in contact with the top surface of the single crystalline substrate layer 10 and are epitaxially aligned to the single crystalline substrate layer 10. Each semiconductor fin in the first device region 100 includes a center portion that overlies the recessed region. The single crystalline semiconductor material of the semiconductor fins is lattice-mismatched with respect to the single crystalline substrate layer 10.

The center portion of each semiconductor fin in the first device region 100 is vertically spaced from a recessed surface of the recessed region. The gate dielectric 50 is formed directly on at least a portion of the recessed surface of the recessed region, and directly on sidewall surfaces, a top surface, and a bottom surface of each of the at least one semiconductor fin. The entirety of the gate dielectric 50 can be formed as a single contiguous structure that includes at least one hole therein. Each center portion of the at least one semiconductor fin passes through one of the at least one hole.

The gate electrode 52 is formed between the recessed surface of the recessed region and the bottom surface of each of the at least one semiconductor fin, and over and around each of the at least one semiconductor fin. Thus, the gate electrode 50 includes a portion located between the recessed surface of the recessed region and the bottom surface of each semiconductor fin. The entirety of the gate electrode 52 can be a single contiguous structure that includes at least one hole therein. The center portion of each semiconductor fin passes through one of the at least one hole.

The gate dielectric 50 contacts at least a portion of the recessed surface of the recessed region, sidewall surfaces of the center portion of each semiconductor fin, a top surface of the center portion of each semiconductor fin, and a bottom surface of the center portion of each semiconductor fin.

The entirety of each semiconductor fin can have the same vertical cross-sectional shape within vertical planes that are perpendicular to the lengthwise direction of the semiconductor fin. In one embodiment, the first and second end portions of each semiconductor fin in the first device region 100 are under the first type of stress along the lengthwise direction of the semiconductor fin, and the center portion of each semiconductor fin can be under the second type of stress that is the opposite of the first type of stress. In one embodiment, the first type of stress can be a compressive stress and the second type of stress can be a tensile stress. In another embodiment, the first type of stress can be a tensile stress and the second type of stress can be a compressive stress. In one embodiment, the raised source region 144 in the first device region 100 and the raised drain region 146 in the first device region 100 can contact a portion of the recessed surface of the recessed region.

The first field effect transistor in the first device region 100 includes a body region 30B including the center portion of a semiconductor fin and having a doping of the first conductivity type, a source region 44 including the first end portion of the semiconductor fin and having a doping of the second conductivity type that is the opposite of the first conductivity type, and a drain region 46 including the second end portion of the semiconductor fin and having the doping of the second conductivity type.

The second field effect transistor in the second device region 200 includes a body region 30B, a source region 44, and a drain region within each of the semiconductor fin located on the single crystalline substrate layer 20 and in the second device region 200. The entirety of the bottom surfaces of the at least one semiconductor fin in the second device region 200 contacts, and is epitaxially aligned to, the single crystalline substrate layer 10. The entirety of the at least one semiconductor fin in the second device region 200 is under the first type of stress along the lengthwise direction of the at least one semiconductor fin in the second device region because of the epitaxial registry of the active material of the at least one semiconductor fin to the virtual substrate material of the single crystalline substrate layer 10 and due to the lattice mismatch between the virtual substrate material and the active material.

In one embodiment, of the first field effect transistor and the second field effect transistor can be a p-type field effect transistor, and the other of the first field effect transistor and the second field effect transistor can be an n-type field effect transistor.

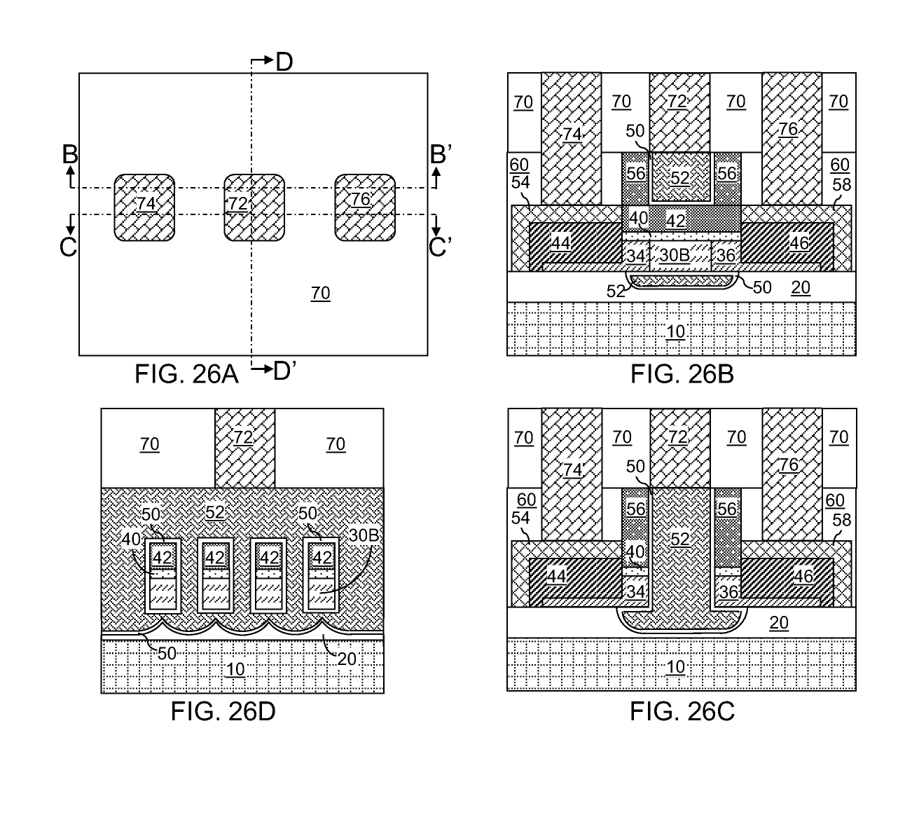

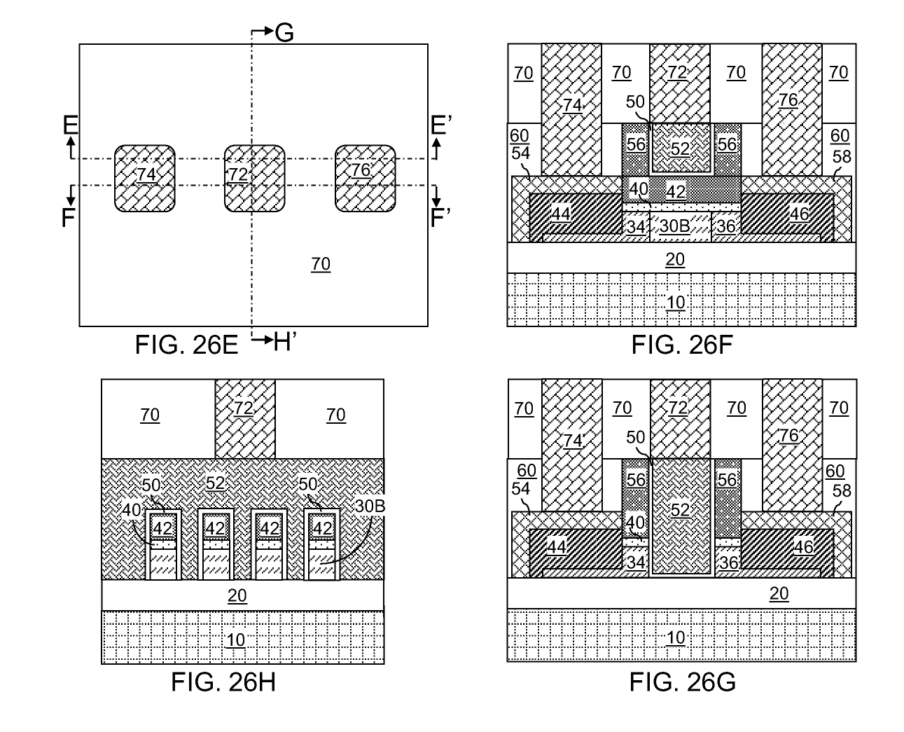

Referring to FIGS. 26A-26H, a contact level dielectric layer 70 and various contact via structures (82, 84, 86) can be formed. FIGS. 26A-26D show various views of the first device region 100, and FIGS. 26E-26H show various views of the second device region 200.

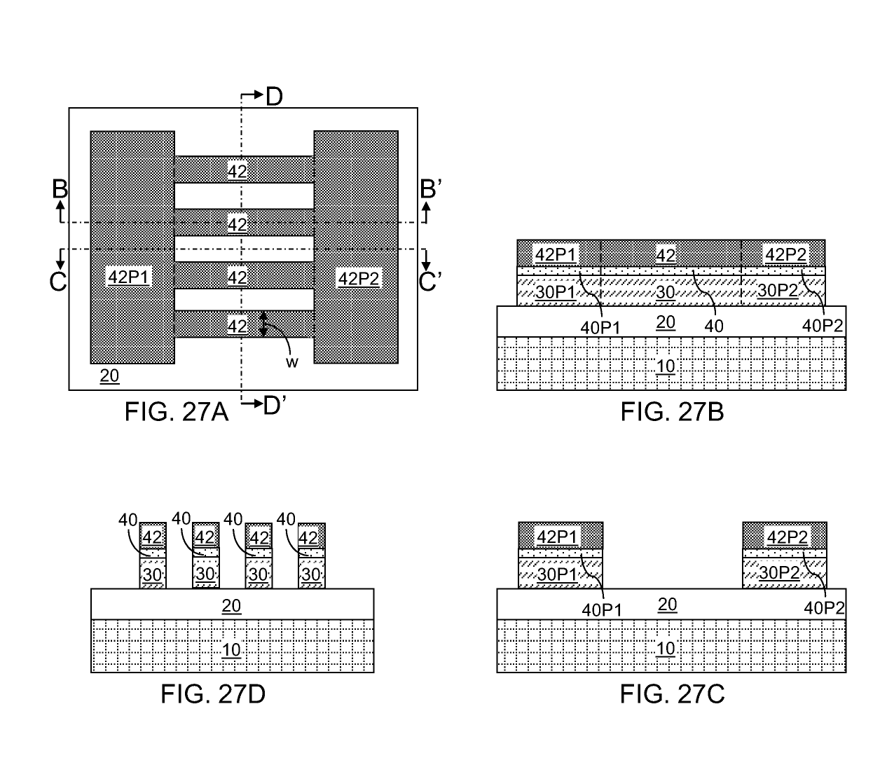

A fourth exemplary semiconductor structure according to an embodiment of the present disclosure includes a first device region and a second device region. A selected region of the first device region and the second device region is illustrated in FIGS. 27A-27D. In other words, the selective region can be the first device region or the second device region. Each of the first device region and the second device region includes a substrate 10, a single crystalline substrate layer 20, and a patterned stack formed thereupon. The substrate 10 can the single crystalline substrate layer 20 can be the same as in other embodiments.

The patterned vertical stack includes a fin-containing semiconductor structure, an optional patterned dielectric liner layer, and a dielectric mask structure. The fin-containing semiconductor structure includes a plurality of semiconductor fins 30, a first semiconductor pad 30P1, and a second semiconductor pad 30P2. Each of the plurality of semiconductor fins 30 is adjoined to the first semiconductor pad 30P1 and the second semiconductor pad 30P2. The optional patterned dielectric liner layer includes a plurality of optional dielectric liner portions 40, an optional first dielectric liner pad 30P1, and an optional second dielectric liner pad 30P2. The dielectric mask structure includes a plurality of fin-defining mask structures 42, a first pad-defining mask structure 42P1, and a second pad-defining mask structure 42P2. The patterned vertical stack can be formed by providing an unpatterned stack of an epitaxial semiconductor layer 30L, an optional dielectric liner layer 40L, and a planar dielectric material layer as in the processing steps of FIGS. 1A and 1B, and by patterning the unpatterned stack by lithographic methods and at least one anisotropic etch.

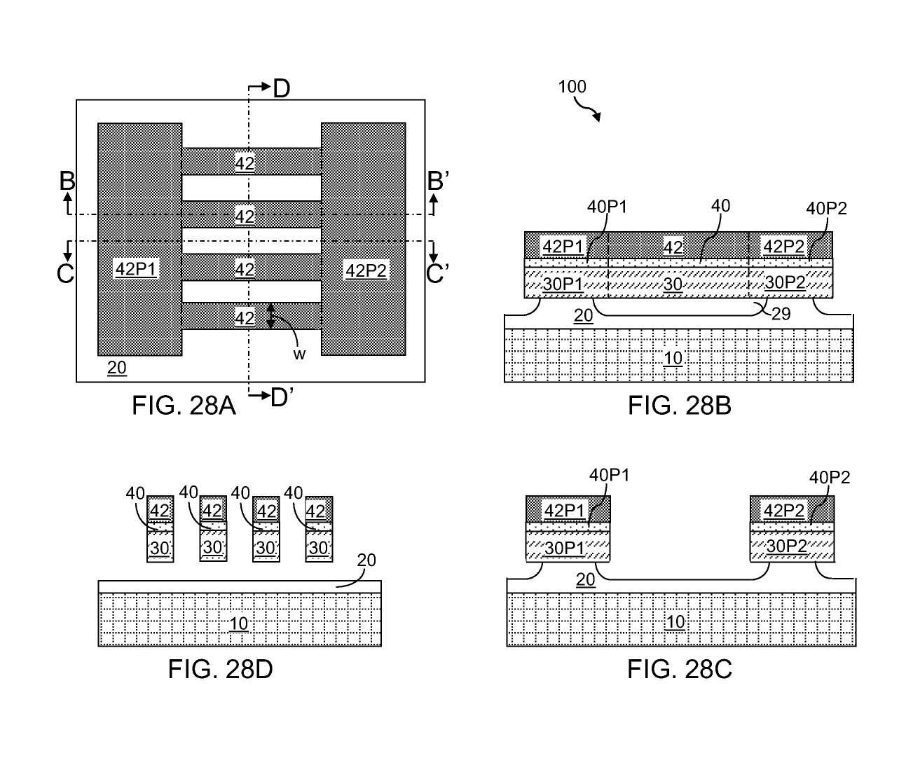

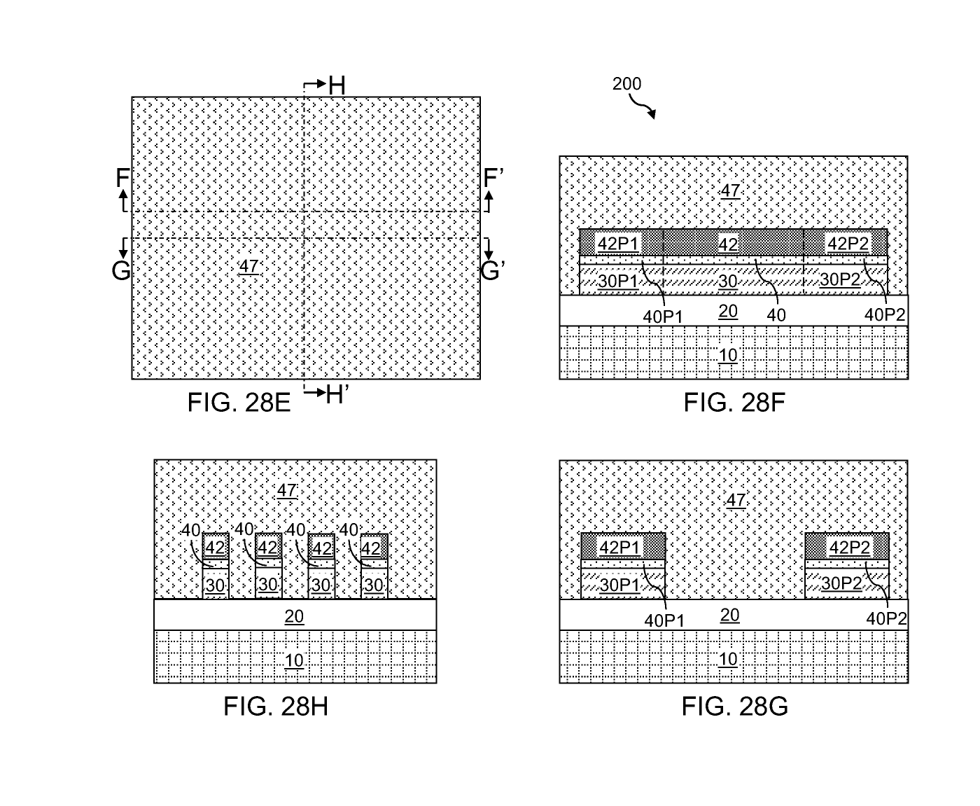

Referring to FIGS. 28A-28H, a patterned photoresist layer 47 is formed over the second device region, while not covering the first device region. Subsequently, the virtual substrate material in physically exposed portions of the single crystalline substrate layer 20 are removed by an isotropic etch selective to the active material in the first device region while the patterned photoresist layer 47 protects materials within the second device region from the etch process. The isotropic etch can be a wet etch or a dry etch. The chemistry of the isotropic etch is selected such that the virtual substrate material is etched selective to the active material, i.e., without significantly etching the active material. The same type of etch chemistry can be employed as in the processing steps of FIGS. 5A-5H. A recessed region 29 is formed in the single crystalline substrate layer 20 underneath the plurality of semiconductor fin 30 in the first device region 100. The first semiconductor pad 30P1 and the second semiconductor pad 30P2 function as an etch mask during the etch process. Thus, the virtual substrate material is removed underneath the periphery of each of the first semiconductor pad 30P1 and the second semiconductor pad 30P2. A center portion of a bottom surface of each of the first semiconductor pad 30P1 and the second semiconductor pad 30P2 contacts the single crystalline substrate layer 20. The plurality of nanowires 30 are suspended over the single crystalline substrate layer 20.

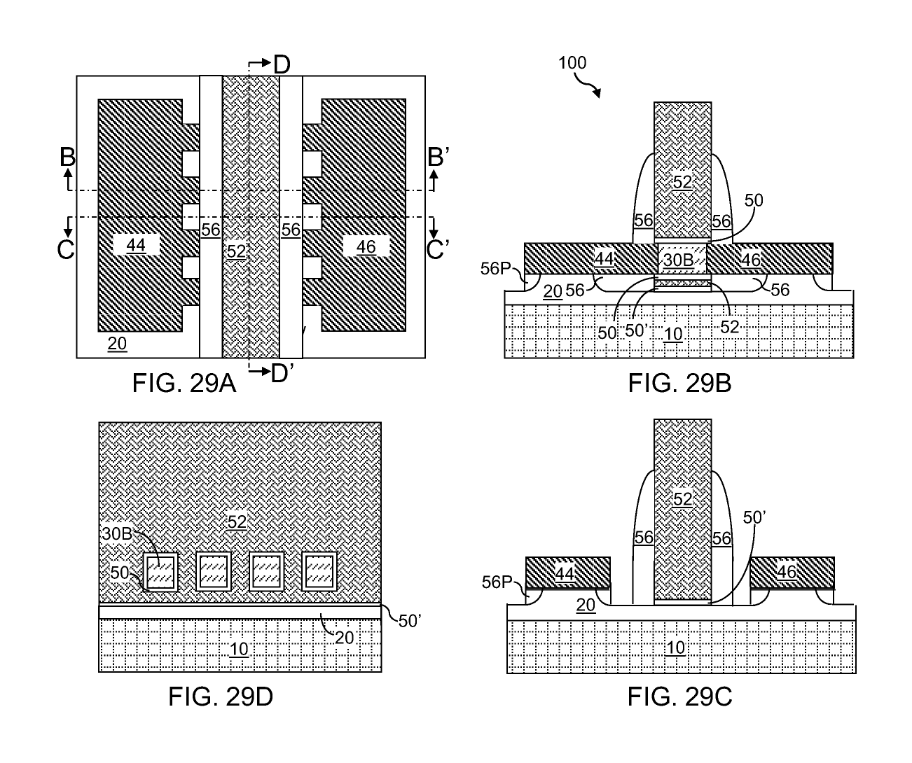

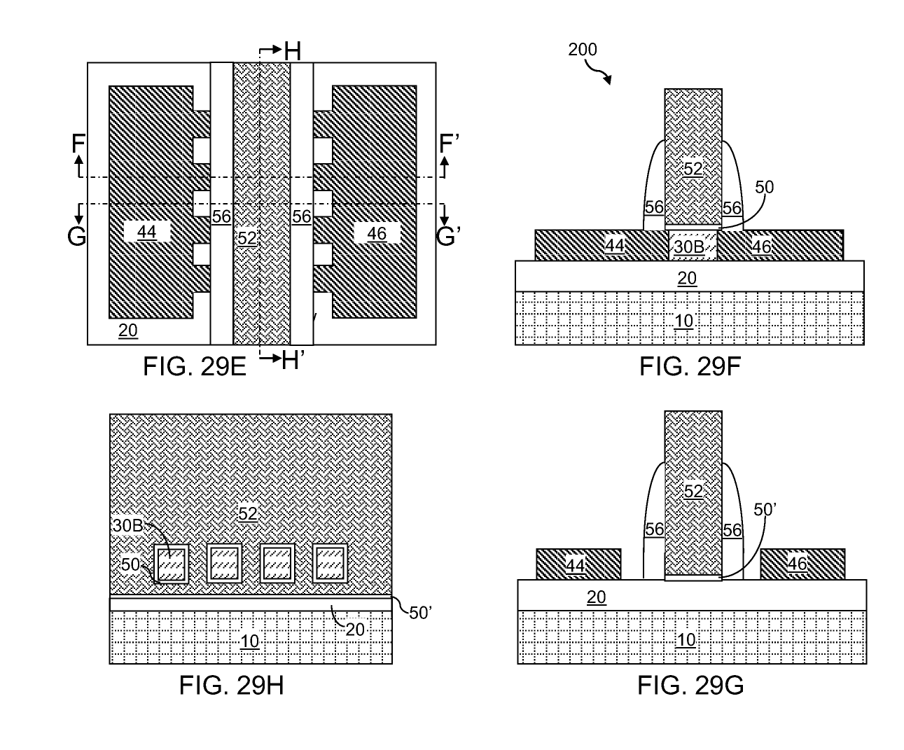

Referring to FIGS. 29A-29H, the processing steps of FIGS. 6A-6D, 7A-7D, and 8A-8H may be performed. Optionally, formation of the raised source regions 144 and the raised drain regions 146 may be omitted. Subsequently, the processing steps of FIGS. 9A-9D may be performed.

Alternately, the processing steps described in FIGS. 10A-10D, 11A-11D, 12A-12D, and 13A-13H may be performed.

While the disclosure has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the disclosure is intended to encompass all such alternatives, modifications and variations which fall within the scope and spirit of the disclosure and the following claims.

What is claimed is:

1. A method of forming a semiconductor structure comprising:
forming at least one semiconductor fin on a single crystalline substrate layer, said at least one semiconductor fin comprising a single crystalline semiconductor material epitaxially aligned to, and lattice-mismatched from, said single crystalline substrate layer and extending along a lengthwise direction; and
forming a recessed region in said single crystalline substrate layer, wherein a first end portion and a second end portion of each of said at least one semiconductor fin remains in contact with a top surface of said single crystalline substrate layer and a center portion of each of said at least one semiconductor fin overlies said recessed region.

2. The method of claim 1, further comprising forming a field effect transistor by:
forming a source region in each first end portion of said at least one semiconductor fin; and
forming a drain region in each second end portion of said at least one semiconductor fin.

3. The method of claim 2, wherein said center portion of each of said at least one semiconductor fin includes a body region of said field effect transistor.

4. The method of claim 2, wherein said first and second end portions of each of said at least one semiconductor fin are under a first type of stress, and center portion is under a second type of stress that is the opposite of said first type of stress.

5. The method of claim 4, wherein said first type of stress is a compressive stress and said second type of stress is a tensile stress.

6. The method of claim 4, wherein said first type of stress is a tensile stress and said second type of stress is a compressive stress.

7. The method of claim 2, further comprising forming a gate dielectric directly on at least a portion of said recessed surface of said recessed region, and directly on sidewall surfaces, a top surface, and a bottom surface of each of said at least one semiconductor fin.

8. The method of claim 7, wherein said gate dielectric includes a hole through which a center portion of one said at least one semiconductor fin passes.

9. The method of claim 7, further comprising forming a gate electrode on said gate dielectric, wherein said gate electrode is formed between a recessed surface of said recessed region and a bottom surface of each of said at least one semiconductor fin, and over and around each of said at least one semiconductor fin.

10. The method of claim 9, further comprising forming a gate spacer around said gate electrode and directly on portions of said recessed surface of said recessed region.

11. The method of claim 10, wherein said gate spacer is formed directly on sidewalls of said gate electrode.

12. The method of claim 9, further comprising:
forming a disposable gate structure over each center portion of said at least one semiconductor fin;
forming a gate spacer around said disposable gate structure; and
removing said disposable gate structure to form a gate cavity, wherein said gate electrode is formed in said gate cavity.

13. The method of claim 12, further comprising forming a gate electrode, wherein said recessed region is formed in said single crystalline substrate layer prior to forming said gate electrode.

14. A semiconductor structure comprising:
a single crystalline substrate layer including a recessed region that is recessed relative to a top surface of said single crystalline substrate layer; and
a semiconductor fin comprising a single crystalline semiconductor material including first and second end portions that are in contact with said top surface of said single crystalline substrate layer and epitaxially aligned to said single crystalline substrate layer and including a center portion that overlies said recessed region, wherein said single crystalline semiconductor material is lattice-mismatched with respect to said single crystalline substrate layer.

15. The semiconductor structure of claim 14, wherein said semiconductor comprises a field effect transistor that includes:
a body region including said center portion and having a doping of a first conductivity type;
a source region including said first end portion and having a doping of a second conductivity type that is the opposite of said first conductivity type; and
a drain region including said second end portion and having a doping of said second conductivity type.

16. The semiconductor structure of claim 15, wherein said first and second end portions are under a first type of stress along a lengthwise direction of said semiconductor fin, and said center portion is under a second type of stress that is the opposite of said first type of stress.

17. The semiconductor structure of claim 16, wherein said first type of stress is a compressive stress and said second type of stress is a tensile stress.

18. The semiconductor structure of claim 16, wherein said first type of stress is a tensile stress and said second type of stress is a compressive stress.

19. The semiconductor structure of claim 15, wherein said field effect transistor further comprises a gate electrode that includes a portion located between a recessed surface of said recessed region and a bottom surface of said semiconductor fin.

20. The semiconductor structure of claim 19, wherein an entirety of said gate electrode is a single contiguous structure that includes at least one hole therein, wherein said center portion of said semiconductor fin passes through one of said at least one hole.

21. The semiconductor structure of claim 19, further comprising a gate dielectric that contacts at least a portion of said recessed surface of said recessed region, sidewall surfaces of said center portion, a top surface of said center portion, and a bottom surface of said center portion.

22. The semiconductor structure of claim 19, wherein said field effect transistor further comprises a gate spacer that laterally surrounds said gate electrode and contacts portions of said recessed surface of said recessed region.

23. The semiconductor structure of claim 19, wherein an entirety of said semiconductor fin has a same vertical cross-sectional shape within vertical planes that are perpendicular to a lengthwise direction of said semiconductor fin.

24. The semiconductor structure of claim 19, further comprising a gate spacer having a bottommost surface that is located at or above a topmost surface of said semiconductor fin.

25. The semiconductor structure of claim 15, wherein said field effect transistor further comprises:
a raised source region that is epitaxially aligned to said source region; and
a raised drain region that is epitaxially aligned to said drain region.
